(19) United States
(12) Patent Application Publication
(10) Pub. No.: US 2007/0286436 A1
(43) Pub. Date: Dec. 13, 2007

(54) SOUND OUTPUT CONTROL DEVICE

(75) Inventors: Yasuhiko Isobe, Kawasaki (JP); Hisashi Negishi, Kawasaki (JP); Yoji Hirosue, Kawasaki (JP); Nobuyuki Kosha, Kawasaki (JP)

Correspondence Address: STAAS & HALSEY LLP, SUITE 700, 1201 NEW YORK AVENUE, N.W., WASHINGTON, DC, 20005, US

(73) Assignee: FUJITSU LIMITED, Kawasaki (JP)

(21) Appl. No.: 11/762,289

(22) Filed: Jun. 13, 2007

Related U.S. Application Data
(63) Continuation of application No. PCT/JP05/22873, filed on Dec. 13, 2005.

(30) Foreign Application Priority Data
Dec. 13, 2004 (JP) PCT/JP04/18583
Dec. 28, 2004 (JP) PCT/JP04/19635

(51) Int. Cl. H03G 3/00

(52) U.S. Cl. 381/107

(57) ABSTRACT

To make it possible to mute voice signals properly according to a headphone or antenna connected. A device for receiving radio signals and outputting voice signals from a first speaker. The device comprises a connection unit having the terminal of an antenna and/or a second speaker connected therewith, a reception unit for receiving the radio signals through the antenna connected with the connection unit, a mute instructing unit for detecting whether or not the terminal has been connected with the connection unit, to output the voice signals to the first speaker, in case the terminal, is not, connected with the connection unit, and to mute the output to the first speaker, in case the terminal is connected with the connection unit, a switch for selecting the activation/deactivation of the mute, and a mute control unit for deactivating the muting function of the mute instructing unit, in case the mute deactivation is selected by the switch, and for outputting the voice signals to the first speaker, even in case the terminal is connected with the connection unit.

### CROSS-REFERENCE TO RELATED APPLICATION

This is a continuation of Application PCT/JP2005/022873, filed on Dec. 13,2005, now pending, the contents of which are herein wholly incorporated by reference.

### BACKGROUND OF THE INVENTION

The present invention relates to a technology of properly muting sounds outputted from an output device such as headphones and an external loudspeaker.

At the present the headphones are highly generally employed as a device for listening to the sounds in the way of being connected to electronic equipment such as a TV set and a radio. Further, with an enhanced function of the electronic equipment, there exist a variety of headphones including a remote control for controlling reproduction (playback) of music, an antenna for a TV tuner, and so on.

FIG. 31 is a schematic diagram of a conventional headphone antenna. A headphone antenna 90 is, as illustrated in FIG. 31, constructed of a speaker unit 91, a cable 92 and a plug 93.

When the headphone plug 93 is connected to the electronic equipment such as a TV set etc, sound signals from the electronic equipment are propagated to the speaker unit 91 via the cable 92 and are output as sounds. Further, in the headphone antenna 90, the cable 92 contains lines 92a, 92b for the sound signals and a line 92c for the antenna, wherein the signals received via the line 92c for the antenna are transmitted to the electronic equipment.

Thus, a space for a connection unit can be saved by use of a unit-type TV (Television) tuner that fits the headphone antenna 90 serving as a function of the headphones and a function of the antenna into a mobile bay of a personal computer.

On the other hand, in the device that thus connects the headphones, if a plug of the headphones is inserted into a jack on the side of the tuner, a device including a mute function that mutes the sound output from the loudspeaker is generally employed.

[Patent document ]

Japanese Patent Application Laid-Open Publication No. 2000-182310

[Patent document 2]

Japanese Patent Application Laid-Open Publication No. 2002-76982

[Patent document 3]

Japanese Patent Application Laid-Open Publication No. 9-116961

[Patent document 4]

Japanese Patent Application Laid-Open Publication No. 10-155191

[Patent document 5]

Japanese Patent Application Laid-Open Publication No. 2002-10389

### SUMMARY OF THE INVENTION

As described above, in the multi-function headphones, there is a case of desiring to use only the functions other than outputting the sounds, however, the conventional headphones are based on a major premise of outputting the sounds and does riot take a scheme enabling only these other functions.

For instance, in the TV tuner having the mute function, whether the sounds are muted or not is decided from determining whether the headphone antenna is connected or not, and hence it follows that the sounds are invariably muted when connecting the headphone antenna. It is therefore impossible to listen to the sounds through the, speaker by using the headphone antenna simply as the antenna.

Such being the case, the present invention provides a technology capable of properly muting the sound output, corresponding to a state of an output device such as the headphones and the headphone antenna.

The present invention adopts the following configurations in order to solve the problems.

Namely, an output device according to the present invention is a device that outputs sounds corresponding to sound signals from electronic equipment, comprising: a connection unit connecting to a connection terminal of the electronic equipment; a wire unit having one edge portion connected to the connection unit and transmitting the sound signals from the electronic equipment; and a relay unit connected to an edge portion, opposite to the connection unit, of the wire unit, relaying the sound signals, and having an attachable/detachable output unit that outputs the sound signals as the sounds, wherein the connection unit includes a state exhibiting unit exhibiting whether or not the output unit is in a state of being connected to the relay unit.

In the output device, the state exhibiting unit may be a terminal having an electric characteristic that differs depending on the connection state between the output unit and the relay unit.

In the output device, the relay unit may include a detection unit detecting whether the output unit is connected to the relay unit or not, and the wire unit may include a signal line transmitting a result of the detection to the connection unit from the relay unit.

In the output device, in the wire unit, the signal, line for an antenna or the signal line transmitting the sound signals may have an antenna function, and the connection unit may include an output terminal outputting, to the electronic equipment, the signals received from the signal line for the antenna or the signal line transmitting the sound signals.

The output device may be a device in the way of being connected to the electronic equipment that mutes the sound signals, corresponding to the electric characteristic of the state exhibiting unit.

In the output device, the output unit may connect to the relay unit in an attachable/detachable manner and may output the sound signals as the sounds from the relay unit.

In the output device, the relay unit may include a switching unit performing switchover as to whether the state exhibiting unit is made to exhibit or not.

In the output device, the state exhibiting unit may include a circuit that closes when the output unit is connected to the relay unit and opens when the output unit is disconnected from the relay unit, and the switching unit may be a switch that opens and closes the circuit separately from the connection.

Further, an output device according to the present invention is a device that outputs sounds corresponding to sound signals from electronic equipment, comprising: a connection unit connecting to a connection terminal of the electronic equipment; a wire unit having one edge portion connected to the connection unit and transmitting the sound signals from the electronic equipment; an output unit connected to an edge portion, opposite to the connection unit, of the wire unit, and outputting the sounds corresponding to the sound signals; and a switching unit positioned between the connection unit and the output unit on the wire unit and switching over a state exhibited to the electronic equipment via the wire unit.

Still further, a sound output control device according to the present invention is a sound output control device in electronic equipment that outputs sounds from a first; speaker, comprising: a mute controlling unit detecting whether or riot a terminal of an antenna and/or a second speaker has been connected a connection unit to which the terminal is connected, making the first speaker output the sound signals when the terminal is not connected to the connection unit, and muting the output to the first speaker when the terminal is connected to the connection unit; and a mute control unit disabling a mute function of the mute indicating unit when a switch for selecting enabled/disabled statuses of the mute selects the mute-disabled status, and outputting the sounds from the first speaker even when the terminal is connected to the connection unit.

The sound output control device may further comprise the switch being provided in the second speaker, a detection unit detecting a state of the switch.

A sound output control device according to the present invention is a sound output control device in electronic equipment that outputs sounds from a first speaker, comprising: a mute control unit detecting a type of a terminal connected to a connection unit to which an antenna and/or a second speaker are or is connected, muting an output to the first speaker when the second speaker is connected to the connection unit, then disabling a mute function when the second speaker is not connected to the connection unit, and thus outputs the sounds from the first speaker.

A sound output control device according to the present invention is a sound output control device in electronic equipment that outputs sounds from a first speaker, comprising: a mute control unit detecting whether or not a second speaker element is connected to an antenna connected to a connection unit to which an attachable/detachable antenna of the second speaker element is connected, muting an output to the first speaker when the second speaker element is connected, then disabling a mute function when the second speaker element is not connected to the connection unit, and outputs the sounds from the first speaker.

In the sound output control device, even when muting the output to the first speaker, if a switch for selecting enabled/disabled statuses of the mute selects the mute-disabled status, may be outputs the sounds from first speaker.

Yet further, a receiving device according to the present invention is a receiving device in electronic equipment that receives radio signals and outputs sounds from a first speaker, comprising: a connection unit to which a terminal of an antenna and/or a second speaker are or is connected; a receiving unit receiving the radio signals via the antenna connected to the connection unit; a mute indicating unit detecting whether or not the terminal is connected to the connection unit, outputting sounds from the first speaker when the terminal is not connected to the connection unit, and muting the output to the first speaker when the terminal is connected to the connection unit; a switch selecting enabled/disabled statuses of the mute; and a mute control unit disabling a mute function of the mute indicating unit when the switch selects the mute-disabled status, arid outputting the sounds from the first speaker even when the terminal is connected to the connection unit.

Moreover, a receiving device according to the present invention is a receiving device in electronic equipment that receives radio signals and outputs sound signals from a first speaker, comprising: a connection unit to which an antenna and/or a second speaker are or is connected; a receiving unit receiving the radio signals via the antenna connected to the connection unit; a mute indicating unit detecting a typo of a terminal connected to the connection unit, muting an output to the first speaker when the second speaker is connected to the connection unit, then disabling the mute function when the second speaker is not connected, and outputting the sound signals to the first speaker.

In the receiving device, even when muting the output to the first speaker, if a switch for selecting enabled/disabled statuses of the mute selects the mute-disabled status, may be output the sounds from the first speaker.

Further, a receiving device according to the present invention is a receiving device in electronic equipment that receives radio signals and outputs sound signals from a first speaker, comprising: a connection unit to which an attachable/detachable antenna of a second speaker element is connected; a receiving unit receiving radio signals via the antenna connected to the connection unit; and a mute control unit detecting whether or not the second speaker element is connected to the antenna connected to the connection unit, muting an output to the first speaker when the second speaker element is connected, then disabling a mute function when the second speaker element is not connected to the connection unit, and outputting the sounds from the first speaker.

In the receiving device, even when muting the output to the first speaker, if a switch for selecting enabled/disabled statuses of the mute selects the mute-disabled status, may be outputs the sounds from the first speaker.

In the receiving device, the switch may be provided in the second speaker.

In the receiving device, the receiving device may be an extended unit connected, exclusively of other extended units, to an extension slot of the electronic equipment.

The receiving device may further comprise a TV tuner unit generating video data and sound data from radio wave signals of a TV broadcast received as radio signals.

Yet further, a receiving system according to the present invention is a system that receives radio signals and outputs sounds from a first speaker, comprising: a connection unit to which a terminal of an antenna arid/or a second speaker are or is connected, a receiving unit receiving the radio signals via the antenna connected to the connection unit; an output unit outputting sounds from the first speaker on the basis of the sound signals, and, on the other hand, muting an output of the sounds in accordance with a mute signal; a mute indicating unit detecting whether or not the terminal is connected to the connection unit, notifying the output unit of the mute signal on the basis of a result of the detection, outputting the sound signals to the first speaker when the terminal is not connected to the connection unit, and muting the output to the first speaker when the terminal is connected to the connection unit; a switch selecting enabled/disabled statuses of the mute; and a mute control unit disabling a mute function of the mute indicating unit when the switch selects the mute-disabled status, and outputting the sounds from the first speaker even when the terminal is connected to the connection unit.

The receiving system may further comprise, the switch being provided in the second speaker, a detection unit detecting a state of the switch.

Additionally, a receiving system according to the present invention is a receiving system that receives radio signals and outputs sounds from a first speaker, comprising: a connection unit to which a terminal of an antenna and/or a second speaker are or is connected; a receiving unit receiving the radio signals via the antenna connected to the connection unit; an output unit outputting sounds from the first speaker on the basis of the sound signals, and, on the other hand, muting an output of the sounds in accordance with a mute signal; and a mute control unit detecting a type of the terminal connected to the connection unit, notifying the output unit of the mute signal on the basis of a result of the detection, muting the output to the first speaker when the second speaker is connected to the connection unit, then disabling a mute function when the second speaker is not connected to the connection unit, and outputting the sounds from the first speaker.

Moreover, a receiving system according to the present invention is a receiving system that receives radio signals and outputs sounds from a first speaker, comprising: a connection unit to which an attachable/detachable antenna of a second speaker element is connected; a receiving unit receiving the radio signals via the antenna connected to the connection unit; an output unit outputting sounds from the first speaker on the basis of the sound signals, and, on the other hand, muting an output of the sounds in accordance with a mute signal; and a mute control unit detecting whether or not the second speaker element is connected to the antenna connected to the connection unit, notifying the output unit of the mute signal on the basis of a result of the detection, muting the output to the first speaker when the second speaker element is connected to the connection unit, then disabling a mute function when the second speaker element is not connected to the connection unit, and outputting the sounds from the first speaker.

In the receiving system, even when muting the output to the first speaker, if a switch for selecting enabled/disabled statuses of the mute selects the mute-disabled status, may be outputs sounds from the first speaker.

The receiving system may further comprise an extension slot capable of exclusively connecting plural types of extended units, where in the connection unit, the receiving unit and the mute indicating unit may be provided as the extended units.

The receiving unit may be TV tuner unit generating video data and sound data from radio wave signals of a TV broadcast received as the radio signals.

It should be noted that in the present invention, the second speaker may be a device outputting the sounds, which can be attached to and detached from the connection unit, such as headphones and an external speaker. Further, the headphones may be a device enabling the individual to listen to the sound outputs in a way that attaches the device to the head etc, such as earphones, ear speakers and bone-conduction speakers.

Moreover, according to the present invention, the sounds may be sufficient if being simply the sounds such as music, voices and electronic sounds but are not limited to the TV sounds composed of human voices, the music, etc.

The present invention enables the sound outputs to be properly muted corresponding to a state of the output device such as the headphones and the antenna.

### BRIEF DESCRIPTION OF THE DRAWINGS

FIG. 1 is a schematic diagram of a headphone antenna according to the present invention.

FIG. 2 is a schematic diagram showing a state where a loudspeaker unit is removed from the headphone antenna.

FIG. 3 is a diagram of an external appearance of the headphone antenna according to the present invention.

FIG. 4 is a diagram of an external appearance of a relay unit.

FIG. 5 is a diagram of an external appearance of the relay unit.

FIG. 6 is an explanatory diagram of a computer to which the headphone antenna is connected.

FIG. 7 is an explanatory diagram of the computer to which the headphone antenna is connected.

FIG. 8 is a diagram of an external appearance of a tuner unit.

FIG. 9 is a schematic diagram of the tuner unit

FIG. 10 is an explanatory diagram of a dedicated antenna.

FIG. 11 is an explanatory diagram of a computer in a second embodiment.

FIG. 12 is a schematic diagram of the headphones in the second embodiment.

FIG. 13 is a schematic diagram of the headphone antenna in a third embodiment.

FIG. 14 is a diagram of an external appearance of the relay unit in the third embodiment.

FIG. 15 is a schematic diagram of the headphones in a fourth embodiment.

FIG. 16 is a schematic diagram of a configuration of a personal computer (receiving system) 2 attached with a tuner unit (receiving device) 1 according to the present invention.

FIG. 17 is an explanatory diagram of a connection unit and a terminal.

FIG. 18 is a diagram showing a state where the terminal is connected to the connection unit.

FIG. 19 is a schematic diagram of a configuration in a sixth embodiment of the present invention.

FIG. 20 is an explanatory diagram of a mute control units.

FIG. 21 is a diagram showing a state where the terminal is connected to the connection unit.

FIG. 22 is a schematic diagram of a configuration in a seventh embodiment of the present invention.

FIG. 23 is an explanatory diagram of the headphone antenna and a mute control unit.

FIG. 24 is a diagram showing a state where the terminal is connected to the relay unit.

FIG. 25 is an explanatory diagram of a terminal of a dedicated antenna.

FIG. 26 is a schematic diagram of an eighth embodiment of the present invention.

FIG. 27 is a perspective view of an external appearance of a tuner unit 1.

FIG. 28 is a schematic view of a configuration of the tuner unit 1.

FIG. 29 is a schematic diagram of a configuration in a first modified example of the eighth embodiment.

FIG. 30 is a schematic diagram of a configuration in a second modified example of the eighth embodiment.

FIG. 31 is a schematic diagram of conventional headphones.

### DESCRIPTION OF THE REFERENCE NUMERALS AND SYMBOLS

1 Luner unit (receiving device)

2 personal computer (electronic equipment, receiving system)

3H headphones

3HA headphone antenna

31 speaker unit

32 relay unit

33 cable

34 connection unit (plug)

10 enclosure

11 connection unit

11a mute indicating unit

12 decoding unit (receiving unit)

14 mute disabling switch

15 mute control unit

21 loudspeaker amplifier (output unit)

22R, 22L loudspeaker

23 headphone amplifier

51 computer main body

52 hinge

53 display unit

54 keyboard unit

56 extension bay

61 FD unit

62 CD-ROM unit

### DETAILED DESCRIPTION OF THE PREFERRED EMBODIMENT

a best mode for carrying out the present invention will hereinafter be described with reference to the drawings. Configurations in the following embodiments are exemplifications, and the present invention is not limited to the configurations in the embodiments.

### <First Embodiment>

§1. Whole Configuration

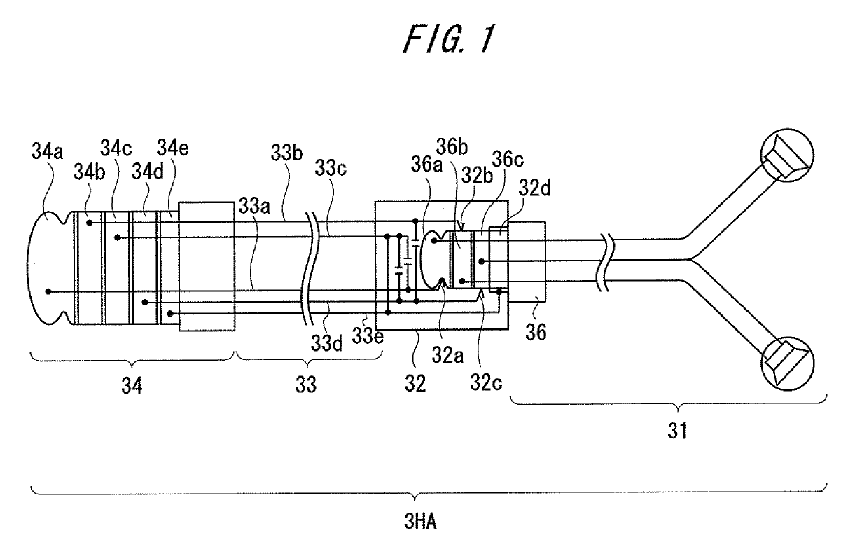

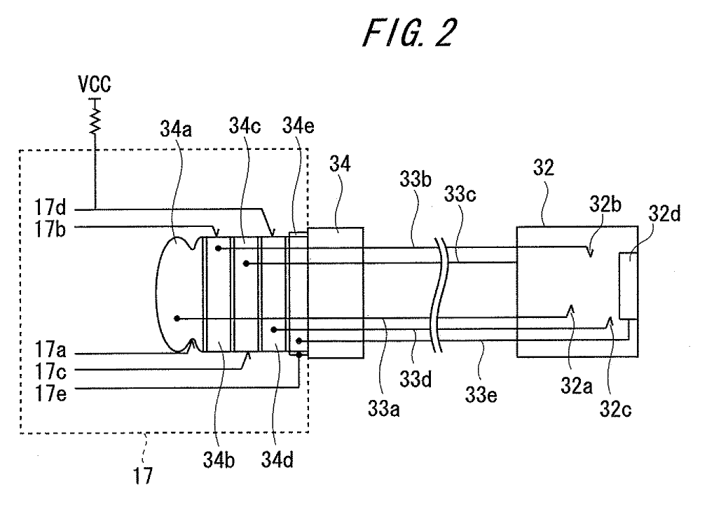

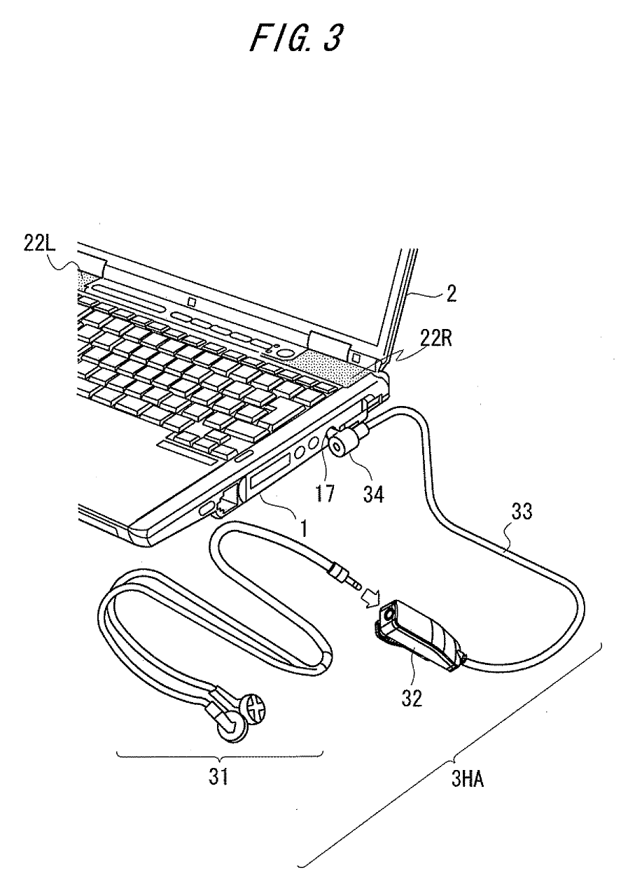

FIG. 1 is a schematic diagram of a headphone antenna (output device) 3HA according to the present invention. FIG. 2 is a schematic diagram showing a state where the headphone antenna 3HA is connected to a connection unit 17 of electronic equipment, while an output unit (speaker unit) 31 is removed. FIG. 3 is a view of an external appearance of the headphone antenna 3HA.

The headphone antenna 3HA in the present embodiment is, as illustrated in FIGS. 1 through 3, constructed of the loudspeaker unit (output unit) 31, a relay unit 32, a cable (wire unit) 33 and a plug (connection unit) 34.

In the headphone antenna 3HA, the plug 34 is connected to the electronic equipment such as a TV set, and, when sound signals are inputted from the electronic equipment, the sound signals are transmitted via the cable 33 to the speaker unit 31 and are output as a sound. The cable 33 of the headphone antenna 3HA includes lines 33a, 33b for the sound signals and a line 33e for GND, and further includes, in addition to these lines, a line 33c for the antenna and a line 33d for transmitting a connection state that will be explained later on. These lines 33a-33e are connected to points 34a-34e of the plug 34. Note that FIGS. 1 and 2 illustrate only the lines (signal lines) as the cable 33, however, these lines are actually coated.

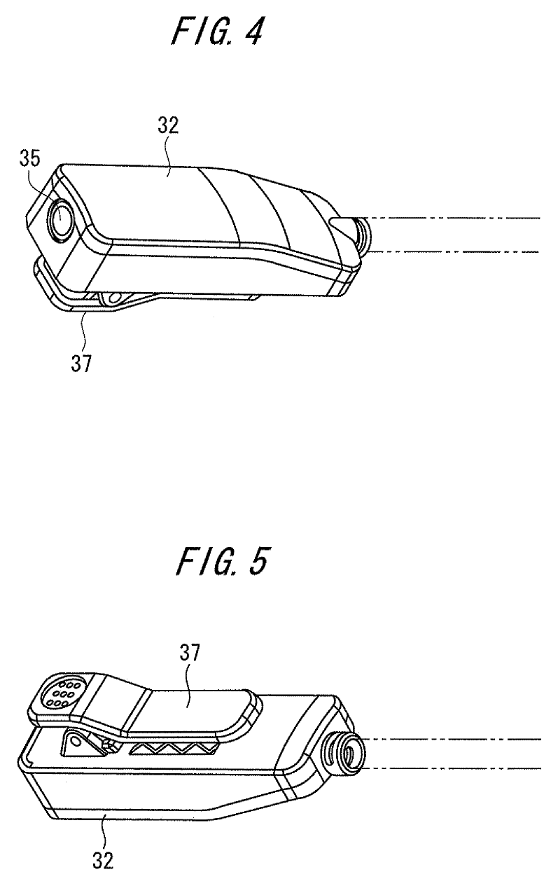

FIGS. 4 and 5 are views of an external appearance of the relay unit 32. As shown in FIG. 4, the relay unit 32 has a jack 35 to and from which a plug 36 of the speaker unit 31 can be attached and detached.

Further, as illustrated in FIGS. 4 and 5, the relay unit 32 has a position-securing portion (which is a clip in this example) for securing the relay unit 32 in an arbitrary position.

The jack 35 of the relay unit 32 has terminals 32a-32d that connect to the lines 33a, 33b, 33d and 33e. In this example, the terminal 32c functions as a detection unit for detecting whether the speaker unit 31 is connected or not.

The terminal 32c of the relay unit 32 is connected to the terminal 32d for the GND via the terminal 36c of the plug 36 in a state where the speaker unit 31 is, as shown in FIG. 1, connected to the relay unit 32. Then, when the speaker unit 31 is disconnected f rom the relay unit 32, as illustrated in FIG. 2, it becomes a no-connect (NC) state. Namely, the terminal (state exhibiting unit) 34e of the plug 34 also changes in terms of electric characteristics to get equivalent to NC when the speaker unit 31 is disconnected from the relay unit 32 and equivalent to GND when the speaker unit 31 is connected to the relay unit 32.

With this scheme, in the electronic equipment to which the headphone antenna 3HA according to the present example is connected, it is possible to determine from the electric characteristics of the terminal 34d of the plug 34 whether the speaker unit 31 is connected or not, i.e., whether the function of outputting the sound from the headphone antenna is enabled (effective) or disabled (ineffective).

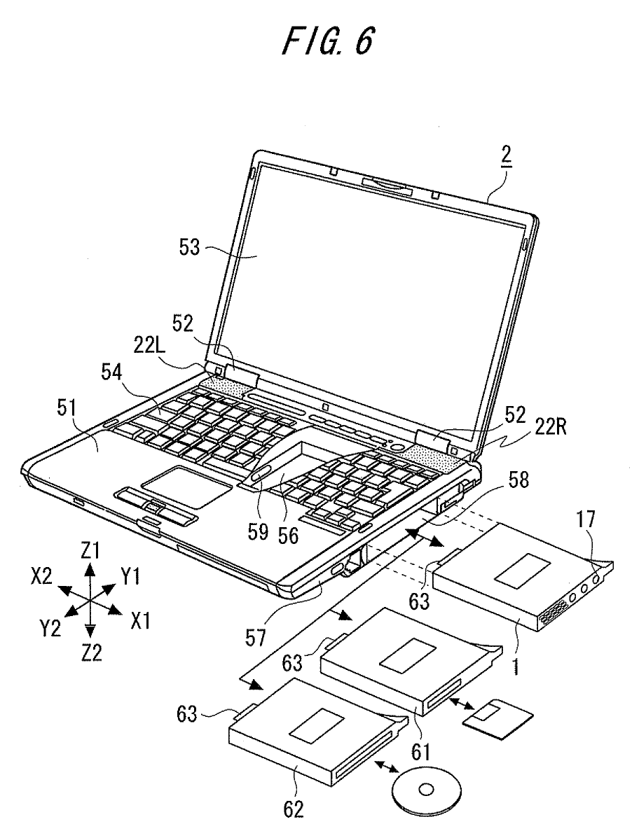

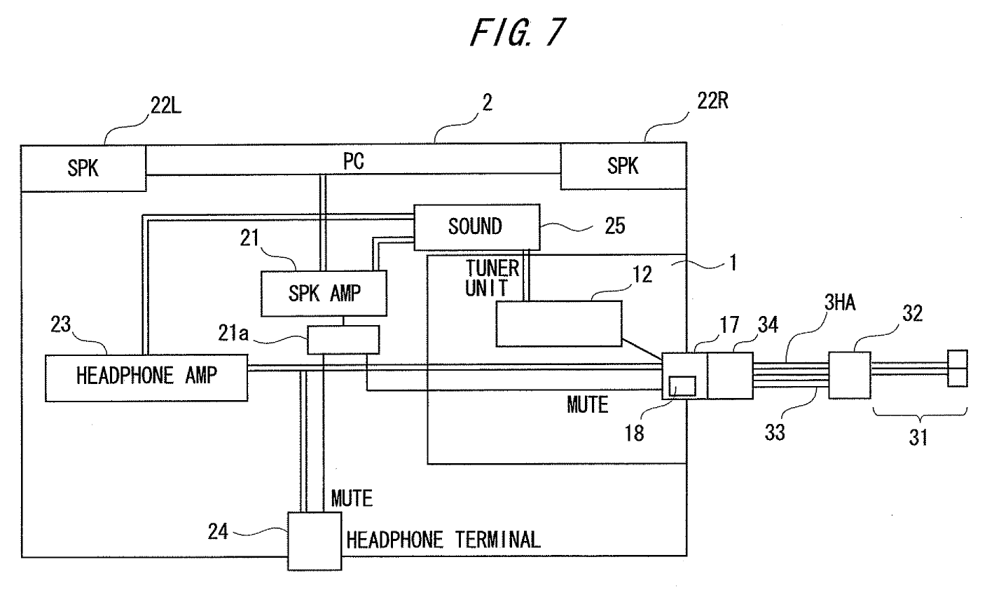

Given next is an explanation of an example of using the headphone antenna 3HA according to the present embodiment for a personal computer (receiving system) 2 attached with a tuner unit (receiving device) 1. The computer 2 detects whether the sound output function of the headphone antenna 3HA is enabled or disabled. The computer 2 mutes the sound output to built-in loudspeakers 22R, 22L when the sound output function is enabled, and outputs the sounds from the loudspeakers by disabling the mute function. FIG. 6 is a view of an external appearance, and FIG. 7 is a schematic diagram of a configuration off the computer.

In FIG. 6, a notebook PC 2 is constructed of a computer main body 51 and a display unit 53 connected to the computer main body 51 in an openable/closable manner via hinges 52. Arrowheads X1, X2 represent a widthwise direction of the notebook PC 2, arrowheads Y1, Y2 represent a depthwise direction, and arrowheads Z1, Z2 indicate a heightwise (thicknesswise) direction. The computer main body 51 has a keyboard unit 54 on its upper surface and a CPU inside, and is formed with an extension bay 56 for accommodating an extended unit in a lower part on the right side. The extension bay 56 has an opening 58 serving as an insertion port for the extended unit in a right-side surface 57 of the computer main body 51. The extension bay 56 takes a slit-like shape extending from the opening 58 up to a middle portion of the device in the direction of the arrowhead X2, and a connector 59 is provided at an X2 side edge portion. Note that the connector 59 is positioned inwardly of the computer main body 51 and is therefore illustrated in a way that cuts off part of the upper surface of the main body 51 in FIG. 6.

Further, the tuner units (receiving device) 1, an FD unit 61 and a CD-ROM unit 62 are prepared as the extended units. Each of these extended units 1, 61, 62 takes a flat-plate-like shape fittable in the extension bay 56, and has a connector 63 fitted to the connector 59 at a front edge portion iii an inserting direction (X2). The units 1, 61, 62 are each exclusively fitted in the extension bay 56. This contrivance enables the notebook PC 2 to access the extended units via the connectors 59, whereby the function thereof can be extended.

Namely, a user selects any one of the tuner unit 1, the FD unit 61 and the CD-ROM unit 62 corresponding to a want-to-use function, and fits the selected unit into the extension bay 56. Note that the extension bay 56 might be designated by a variety of terms such as a bays an extension slot, a multi-bay and a multi-purpose bay.

Then, as illustrated in FIG. 7, the tuner unit 1, when fitted into the extension bay 56 of the notebook PC 2, receives a TV broadcast and outputs video signals and sound signals to the notebook PC 2. The sound signals are converted into signals in a predetermined format by a sound chip 25 and are thereafter output to a loudspeaker amplifier (output unit) 21 and a headphone amplifier 23. The loudspeaker amplifier (output unit) 21 amplifies the sound signals and thus outputs the sounds from the loudspeakers 22R, 22L. Further, the headphone amplifier 23 amplifies the sound signals and thus outputs the sounds from the headphones connected to a headphone jack 17 and to a headphone jack 24. Incidentally, such a connection may be established that the signals from the sound chip 25 are output directly to the headphone jack 17 and to the headphone jack 24 without using the headphone amplifier 23.

The loudspeaker amplifier 21 has a mute function and mutes the sound outputs from the loudspeakers 22R, 22L, corresponding to mute signals given from the jacks 17, 24. It is to be noted that a Low mute signal is output when the headphones are connected to the jacks 17, 24, and a High mute signal is output when not connected according to the present embodiment. The outputs of the jacks 17, 24 are inputted to the loudspeaker amplifier 21 via an AND circuit 21a. Then, the loudspeaker amplifier 21 mutes the outputs from the loudspeakers 22R, 22L when an output of the AND circuit 21a is Low. Namely, the outputs to the loudspeakers 22R, 22L are muted if the headphones are connected to one of the jacks 17, 24. In a state where the headphones are not connected to the jack 24, there will be described operations of the mute function when the headphones are connected to the jack 17 and when not connected.

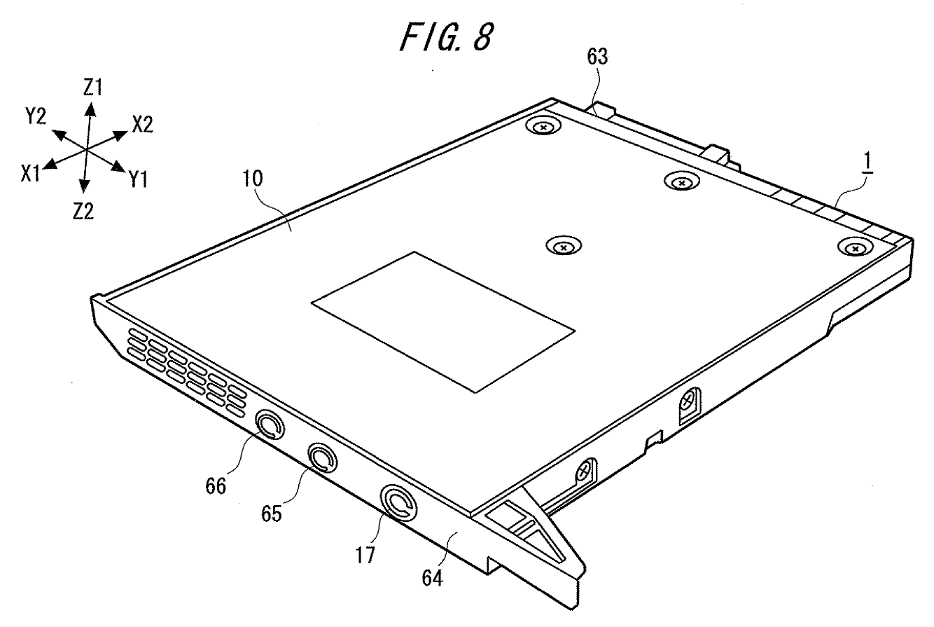

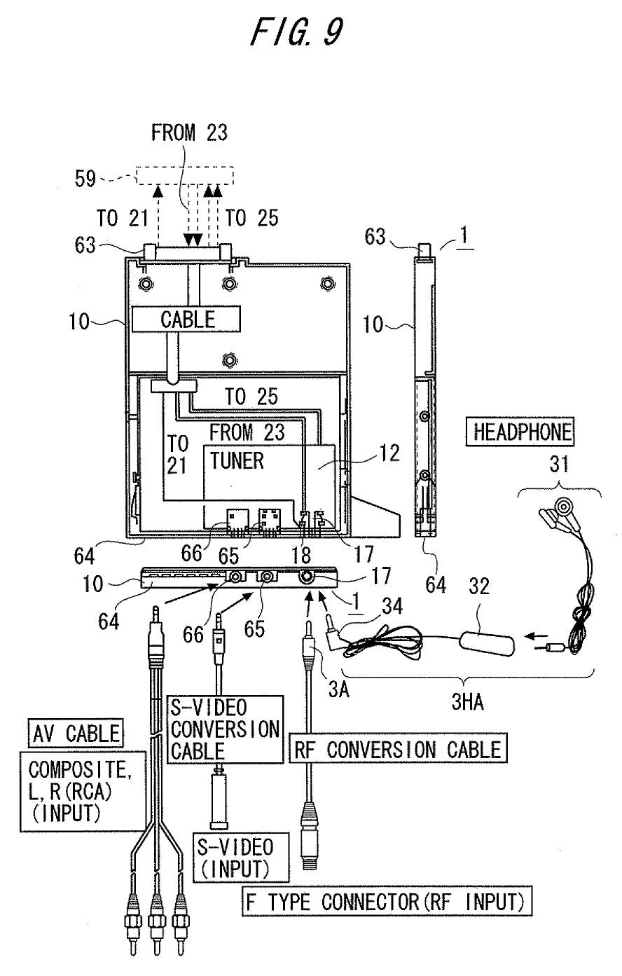

FIG. 8 is a perspective view of an external appearance of the tuner unit 1. FIG. 9 is a schematic diagram of a configuration of the tuner unit 1. As described above, an enclosure 10 takes substantially a flat-plate-like shape as an external configuration thereof, and is provided with a connector 63 protruding from a front edge surface in its inserting direction (X2-direction) Further, a headphone jack (connection unit) 17, an S-video input terminal 65 and a composite input terminal 66 are provided in line on a rear edge surface in the inserting direction, i.e., an external cladding surface 64 that is positioned outside when fitted into the extension bay 56 and is flush with a right side surface of the notebook PC 2.

As illustrated in FIG. 9, the tuner unit 1 includes the jack 17, a decoding unit (receiving unit) 12 and a mute control unit 18. A terminal (plug) of an antenna 3A or the headphone antenna 3HA is, as shown in FIG. 2, connected to the jack 17.

The decoding unit 12 generates video signals and sound signals based on radio signals (TV broadcast) received via antenna elements of the antenna 3A or the headphone antenna 3HA connected to the jack 17.

As illustrated in FIG. 2, the jack 17 on the side of the TV tuner has terminals 17a-17e for left-and-right sound signals, the antenna, the mute signal and GND, and the terminals 17a-17e are respectively connected to the terminals 34a-34eof the headphone antenna 3HA.

The mute control unit 18 applies a predetermined voltage (e.g., Vcc=3 V through 5V) to the terminal 17d of the connection unit 17. Therefore, in a state where the plug 36 of the speaker unit 31 is not inserted into the relay unit 32, the terminal 34d comes to a High state of a predetermined voltage value. Namely, the mute, control unit 18 sets “High” (disables the mute function) the mute signal transmitted to the loudspeaker amplifier 21, thereby outputting the sounds from the loudspeakers 22R, 22L. In the present embodiment, the connection unit 17 for detecting the states of the output devices 3H, 3HA and the mute control unit 18 controlling the sound output based on the electric potential of the terminal 17d of the connection unit, build up a sound output control device in the computer 2.

On the other hand, when the plug 36 is inserted into the relay unit 32, as illustrated in FIG. 1, the terminal (detecting unit) 32c and the terminal 32d of the relay unit 32 becomes conductive via the plug 36, and the terminal 17d on the side of the TV tuner comes to the Low state equivalent to (approximately 0 V) to GND. Namely, the mute control unit 18 sets “Low” (enables the mute function) the mute signal transmitted to the loudspeaker amplifier 21, thereby muting the outputs to the loudspeakers 22R, 22L.

Through this operation, in the present embodiment, the mute function can be so controlled as to be enabled or disabled depending on whether the speaker unit 31 is connected to the relay unit 32 or not.

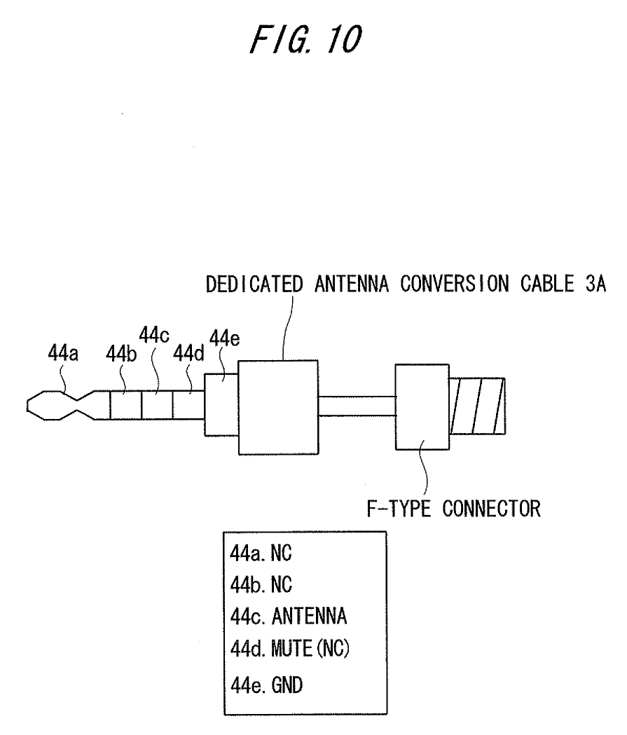

Note that the antenna 3A as shown in FIG. 10 may also be connected to the connection unit 17. In the terminals of the antenna 3A that does not serve as the headphones, the terminal 44d for the mute signal comes to the NC (No-Connect) state. Even in this case, when the antenna 3A is connected to the connection unit 17, the terminal 17d is kept “High”, and hence the mute control unit 18 can disable the mute function by setting “High” the mute signal.

As described above, according to the present embodiment, the connection state of the speaker unit 31 can be exhibited, and therefore the mute function can be properly controlled on the side of the notebook PC 2. With this contrivance, for example, when individually desiring for listening to the sounds, the speaker unit 31 is connected to the relay unit 32, the sounds of the TV broadcast received via the line for the antenna are heard via the headphone antenna 3HA. If plural persons want to listen to the sounds, the speaker unit 31 is disconnected from the relay unit 32, and the sounds of the TV broadcast received via the line for the antenna are heard from the loudspeakers 22R, 22L, thus selecting a listening mode. In the present embodiment, as described above, it is feasible to select whether the sounds are output from the loudspeakers 22R, 22L or not, depending on whether the speaker unit 31 is connected or disconnected, whereby it is possible to provide the device of which operability is good enough to enable the user to intuitively operate. Then, in this case also, the antenna can continue to function effectively.

Further, the relay unit 32 is provided with the clip 37, whereby the relay unit 32 can be fixed in an arbitrary position even when removing the loudspeaker unit attached to the ear of the user by fixing the clip 37 to the clothing of the user. The antenna can be thus kept in a high receiving sensitivity position, e.g., a high position.

Further, even when connecting the dedicated antenna 3A to the connection unit 17, the outputs to the loudspeaker is 22R, 22L are not muted, and the connection unit 17 to the headphone antenna 3HA and the dedicated antenna 3A can be communized.

It should be noted that the present embodiment can be applied widely to, other than the TV tuner, the electronic equipment with the antenna and the headphones connected to each other, such as a radio, a mobile phone and a portable TV.

Note that the line 33c for the antenna is separately provided in the present embodiment, however, this dedicated line 33c is not necessarily provided. The TV broadcasting signals and the sound signals are different in terms of frequency bands, and hence, if the signals of the frequency band for the TV broadcasting signals, which are propagated through the lines 33a, 33b for the sound signals, are separated and extracted by the main body of the notebook PC, it follows that the TV broadcasting signals can be received.

Such being the case, the present invention provides the technology by which the output unit is made attachable and detachable, whether the sound output function is enabled or disabled is indicated by exhibiting the connection state of the output unit, and the functions other than this sound output function can be properly utilized.

### <Second Embodiment>

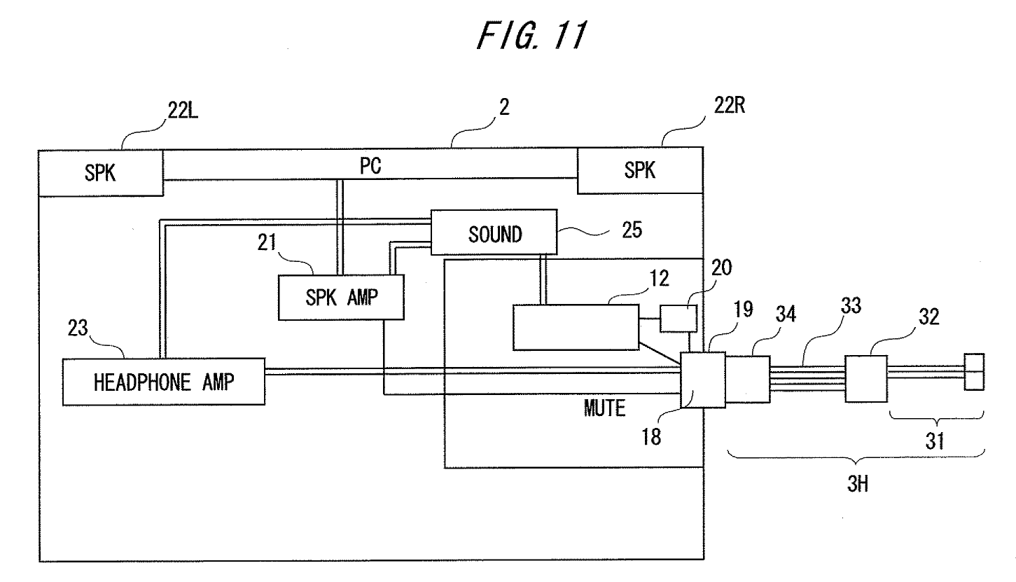

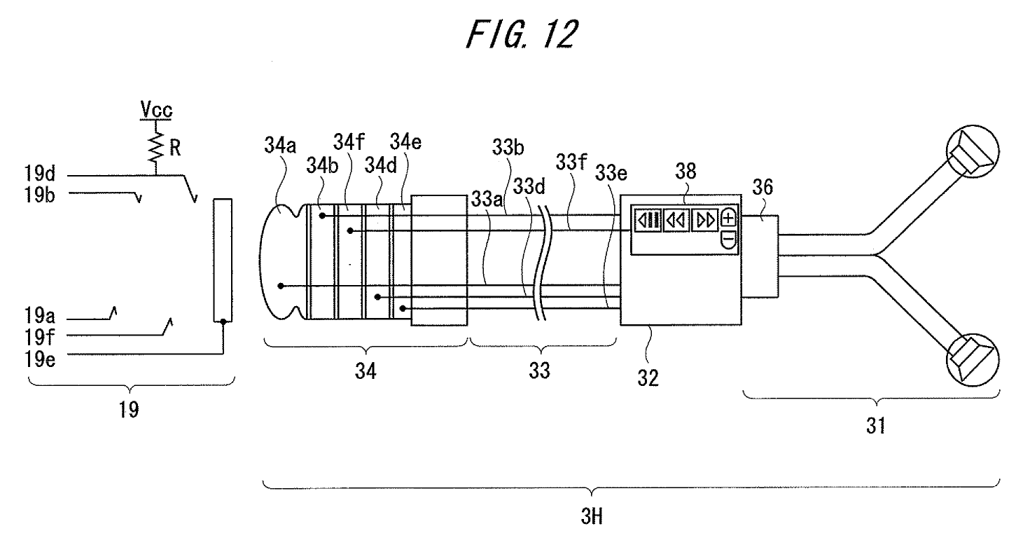

FIGS. 11 and 12 are schematic diagrams each showing a configuration in a second embodiment of the present invention. The second embodiment exemplifies an example of the headphones including a controller. Note that the same members as those in the first embodiment discussed above are marked with the same reference numerals and symbols, and their repetitive explanations are omitted.

As illustrated in FIGS. 11 and 12, in headphones 3H in the second embodiment, the relay unit 32 includes a controller 38, and a control signal from this controller 38 is connected (inputted) to the terminal 34f of the plug 34 via the line 33f for the control signal. When the headphones 3H in the present example are connected to a connection unit 19 of the notebook PC 2, the control signal is transmitted to a control unit 20 from a terminal l9f of the connection unit 19, thereby performing the control of reproducing and stopping a piece of music, changing a volume and so on. Note that the line extending from the controller 38 to the control unit 20 and the terminal are illustrated as the single elements for the convenience's sake, however, without being limited to these single elements, arbitrary numbers of lines and terminals may be provided corresponding to the number of functions to be controlled.

Further, the loudspeaker amplifier 21 in the second embodiment receives a result of detecting whether or not the speaker unit 31 is connected from the control unit 18 on the basis of an electric potential of the terminal 18d of the jack 19, and performs the control to output the sound signals in a sound field for the headphones when the headphones are connected (when the receiving signal is “Low”) and to output the sound signals in a sound field for the loudspeaker when the headphones are not connected (when the receiving signal is “High”). It is to be noted that the mute control may be conducted corresponding to the result of this detection according to the second embodiment in the same way as in the first embodiment discussed above.

According to the second embodiment, as described above, the connection state of the speaker unit 31 can be exhibited, and hence the setting of the sound field can be properly controlled on the side of the notebook PC. Moreover, since only the speaker unit 31 can be disconnected, the remote control function can be solely utilized while disabling the sound output function of the headphones 3H.

### <Third Embodiment>

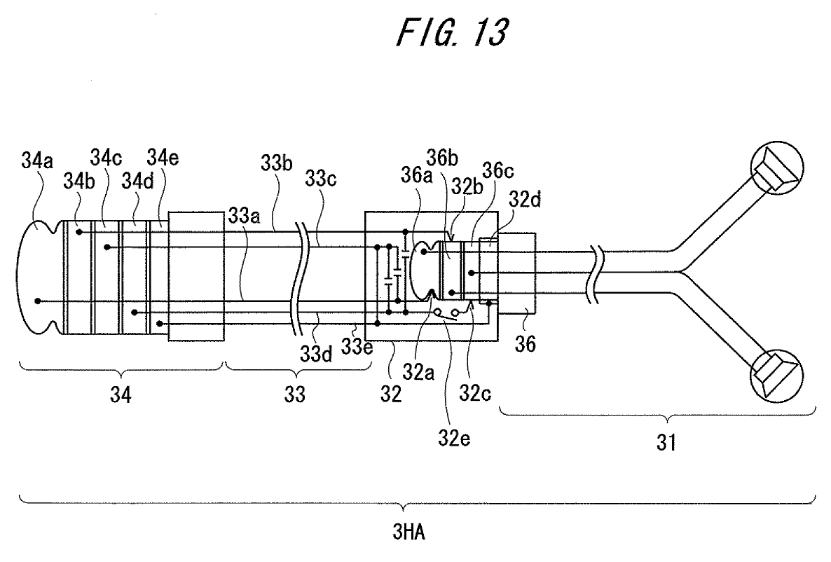

FIG. 13 is a schematic diagram in a third embodiment according to the present invention. The third embodiment is different from the first embodiment discussed above in terms of a point that the connection unit 32 is provided with a switch 32e for disabling the mute. Note that other constructions are substantially the same as those in the first embodiment, and the repetitive explanations are omitted in a way that marks the same components with the same numerals and symbols.

As illustrated in FIG. 13, the mute disabling switch 32e is provided between the terminal 32c of the relay unit 32 and the terminal 34d of the plug 34, and switches over opening/closing states of the line 33d for the mute.

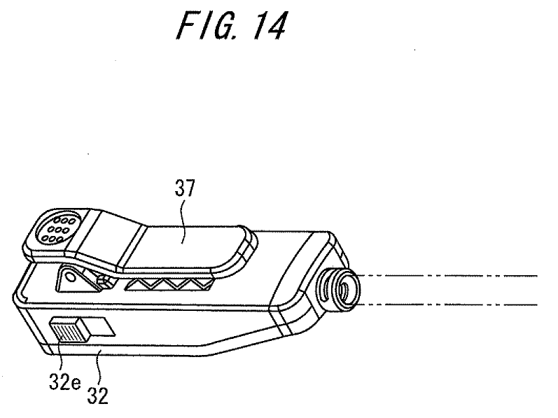

FIG. 14 is a view of an external appearance of the relay unit 32 provided with the mute disabling switch 32e. In the third embodiment, the user arbitrarily switches over the enabled/disabled statuses of the mute function by manipulating the mute disabling switch 32e provided on the side surface of the relay unit 32.

Namely, if the mute disabling switch 32e is closed, similarly to the first embodiment discussed above, the sound outputs from the built-in loudspeakers 22R, 22L are muted when the speaker unit 31 is connected to the relay unit 32 but are not muted when the speaker unit 31 is not connected to the relay unit 32.

Then, it the mute disabling switch 32e is in an opened state, the mute function can be invariably disabled because the electric potential of the terminal (detecting unit) 17d of the jack 17 does not decrease down to “Low” even when the speaker unit 31 is connected to the relay unit 32.

Therefore, according to the third embodiment, the enabled/disabled statuses of the mute function can be arbitrarily set such as disabling the mute function while the speaker unit 31 remains connected to the relay unit 32. Namely, if a gain of the radio signal is lowered when disconnecting the speaker unit 31, the sounds can be output from the built-in loudspeakers 222R, 22L while the speaker unit 31 remains connected.

### Fourth Embodiment>

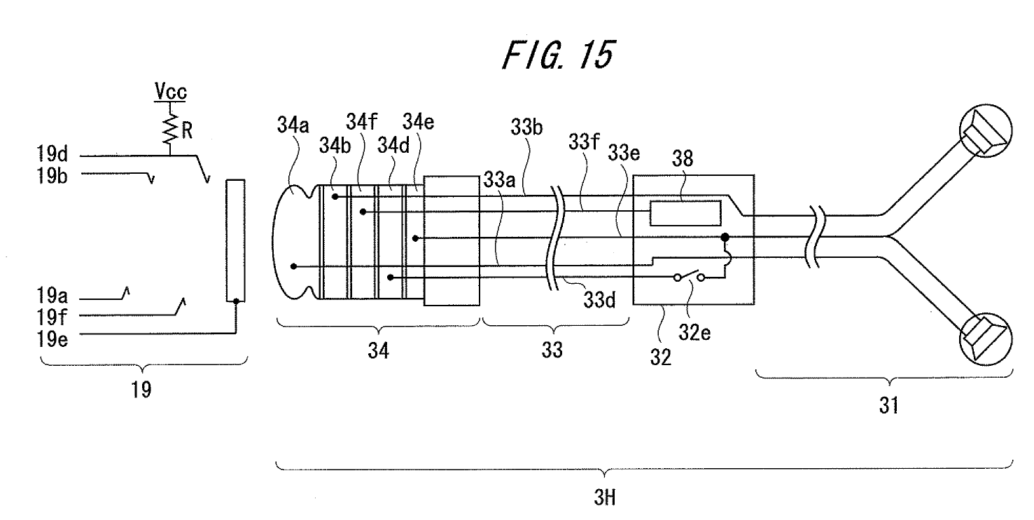

FIG. 15 is a schematic diagram o a fourth embodiment according to the present invention. The fourth embodiment is different from the second embodiment discussed above in terms of a point that the speaker unit 31 is fixed to the relay unit (which is referred to as an operation unit in the present example) and a point that the operation unit 32 is provided with a switch 32e for disabling the mute. Note that other constructions are substantially the same as those in the second embodiment, and the repetitive explanations are omitted in a way that marks the same components with the same numerals and symbols.

As illustrated in FIG. 15, the mute disabling switch 32e is, within the operation unit 32, connected to the mute line 33d extending from the terminal 34d of the plug 34 and to the ground line 33e.

Namely, the electric potential of the terminal (detecting unit) 19d of the jack 19 can be switched over to “High” or “Low” by opening or closing the mute disabling switch 32e.

Hence, according to the fourth embodiment, the user can arbitrarily switch over the enabled/disabled statuses of the mute function at hand (by the operation unit) without even making attachable the loudspeaker unit.

### <Fifth Embodiment>

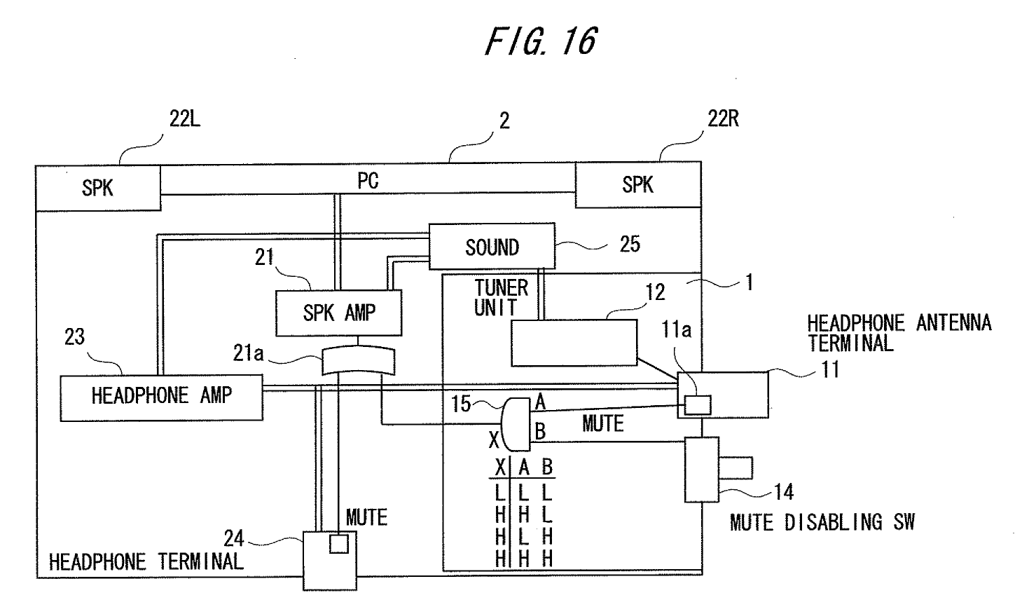

FIG. 16 is a schematic diagram of a configuration of the personal computer (receiving system, electronic equipment) 2 attached with the tuner unit (receiving device) 1 according to the present invention.

The tuner unit 1 in the present example, which is inserted into a card slot of the personal computer (PC) 2, receives the TV broadcast and outputs the video signals and the sound signals to the PC 2. The sound signals are converted into signals in a predetermined format by the sound chip 25 and are thereafter output to the loudspeaker amplifier (output unit) 21 and the headphone amplifier 23. The loudspeaker amplifier (output unit) 21 amplifies the sound signals and thus outputs the sounds from the loudspeakers 22R, 22L. Further, the headphone amplifier 23 amplifies the sound signals and thus outputs the sounds from the headphones connected to the headphone antenna terminal (connection unit) 11 and to the headphone jack 24.

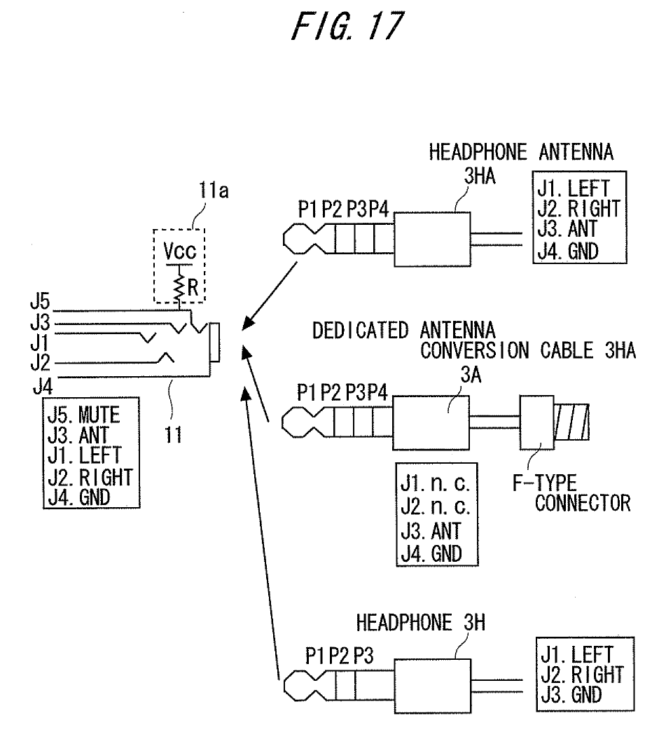

As shown in FIG. 16, the tuner unit 1 includes the connection unit 11, a mute indicating unit 11a, a decoding unit (receiving unit) 12, a mute disabling switch 14 and a mute control unit 15. A terminal (plug) of the antenna 3A or the headphones (second loudspeaker) 3H or the headphone antenna (the antenna to and from which a second loudspeaker is attachable and detachable) 3HA is, as illustrated in FIG. 17, connected to the connection unit (jack) 11.

The decoding unit 12 generates the video signals and the sound signals on the basis of the radio signals (TV broadcast) received via the antenna elements of the antenna 3A or the headphone antenna 3HA connected to the connection unit 11.

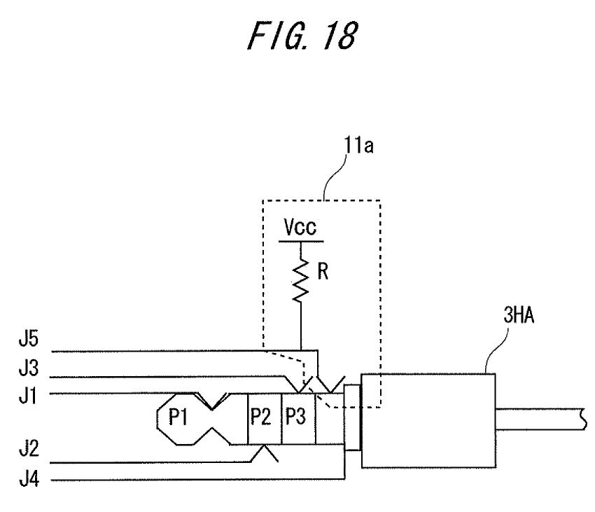

The mute indicating unit 11a outputs the mute signal, depending on whether the terminal is connected to the connection unit 11 or not. With this operation, if the terminal is not connected to the connection unit 11, the sound signals are output to the loudspeakers 22R, 22L, and, whereas if the terminal is connected to the connection unit 11, the outputs to the loudspeakers 22R, 22L are muted. Specifically, as shown in, FIG. 17, the mute indicating unit 1a takes such a construction that a grounded contact point J4 and a contact point J5 of the connection unit 11 are arranged side by side, and a predetermined voltage (e.g., Vcc=3 V to 5 V) is applied to the contact point J5. Owing to this construction, in a state where the terminal in FIG. 2 is not inserted, an output of the contact point J5, which serves as the mute signal, becomes the “High” state of the predetermined voltage value. While on the other hand, when the terminal (FIG. 18 shows an example of the terminal of the headphone antenna 3HA) is inserted into the connection unit 11, as illustrated in FIG. 18, the contact point J5 and the contact point J4 become conductive via the terminal, and the output of the contact point J5 becomes, as the mute signal, the “Low” state equivalent (approximately 0 V) to GND. Note that the connected/unconnected states of the terminal are electrically detected in the present example, however, without being limited to this type of detection, there may be an available scheme capable of outputting the mute signal corresponding to the connecting state of the terminal such as mechanically detecting the contact with the terminal by a switch when connected, and photo-electrically detecting the contact by a photo coupler.

The mute disabling switch (switching unit) 14 outputs the mute control signal corresponding to the enabled/disabled statuses of the mute signal, which are selected through the manipulation of the user. In the present example, the mute disabling switch 14 outputs the mute control signal so as to become “Low” when the mute is enabled and “High” when the mute is disabled.

The mute control unit 15, when the switch 14 selects the mute disabled status, disables the mute function, and outputs the mute signal in the “High” state even when the terminal is connected to the connection unit 11 (Low). Namely, the mute control unit in the present example takes OR (logical sum) of the mute signal and the mute control signal of the switch 14, and thus outputs the signal.

In the fifth embodiment, the sound output control device in the computer 2 is constructed of the mute indicating unit 11a that outputs the mute signal depending on whether the output devices 3H, 3HA arc connected to the connection unit 11 or not, the mute disabling switch 14 that switches over the enabled/disabled statuses of the mute, acid the mute control unit 15 that controls the sound outputs based on the states of the mute indicating unit 11a and of the mute disabling switch 14.

It is to be noted that the front part of the PC 2 is provided with a headphone jack 24, wherein the “Low” mute signal is output when the headphone terminal is connected, and the “High” mute signal is output when the headphone terminal is not connected as in the case of the connection unit 11 in the fifth embodiment. The outputs of the mute control unit 15 and the headphone jack 24 are inputted to the loudspeaker amplifier 21 via an AND circuit 21a.

Then, the loudspeaker amplifier 21 mutes the outputs of the loudspeakers 22R, 22L when an output of the AND circuit 21a is “Low”. To be specific, if the output of any one of the mute control unit 15 and the headphone jack 24 is “Low”, the outputs to the loudspeakers 22R, 22TT,are muted. Given hereinafter is description of an operation of how the mute function is selected when the terminal is connected to the connection unit 11 and when the terminal is not connected to the connection unit 11 in a state where the terminal is not connected to the headphone jack 24.

When the switch 14 is in an effective state and when the terminal is not connected to the connection unit 11, the tuner unit 1 in the fifth embodiment sets “High” the mute signal given from the mute indicating unit 11a and sets “High” the output of the mute control unit 15, thereby making the loudspeaker amplifier 21 output the sound signals to the loudspeakers 22R, 22L.

Further, when the switch 14 is in the effective state and when the terminal is connected to the connection unit 11, the tuner unit 1 sets “Low” the mute signal given from the mute indicating unit 11a and sets “Low” the output of the mute control unit 15, thereby muting the sound signals from the loudspeaker amplifier 21 to the loudspeakers 22R, 22L.

Moreover, when the switch 14 is in an ineffective state and when the terminal is not connected to the connection unit 11, the tuner unit 1 in the fifth embodiment sets “High” the mute signal given from the mute indicating unit 11a and sets “High” the output of the mute control unit 15, thereby making the loudspeaker amplifier 21 output the sound signals to the loudspeakers 22R, 22L.

Then, when the switch 14 is in the ineffective state and when the terminal is connected to the connection unit 11, the tuner unit 1 sets “Low” the mute signal given from the mute indicating unit 11a but sets “High” the output of the mute control unit 15 because of the output of the mute disabling switch 14 being “High”, thereby making the loudspeaker amplifier 21 output the sound signals to the loudspeakers 22R, 22L.

As described above, according to the fifth embodiment, the mute disabling switch 14 can disable the mute function when the terminal is connected to the connection unit 11. With this contrivance, for example, in the case of carrying the PC 2 outdoors and thus using the PC 2, the headphone antenna 3HA is connected to the connection unit 11, whereby the sound signals received via this antenna unit 3HA are heard through the headphones. In the ase of using the PC 2 indoors, the dedicated antenna 3A is connected to the connection unit 11, whereby the sound signals received via the antenna 3A can be heard through the loudspeaker.

Accordingly, in the receiving device 1 constructed to connect the antenna and the headphones to the same connection unit and scheming to simplify the device, to reduce the number of components and to save the space, the sound signals can be output from the loudspeaker by selectively disabling the mute function even in the case of connecting the antenna to the connection unit.

### <Sixth Embodiment>

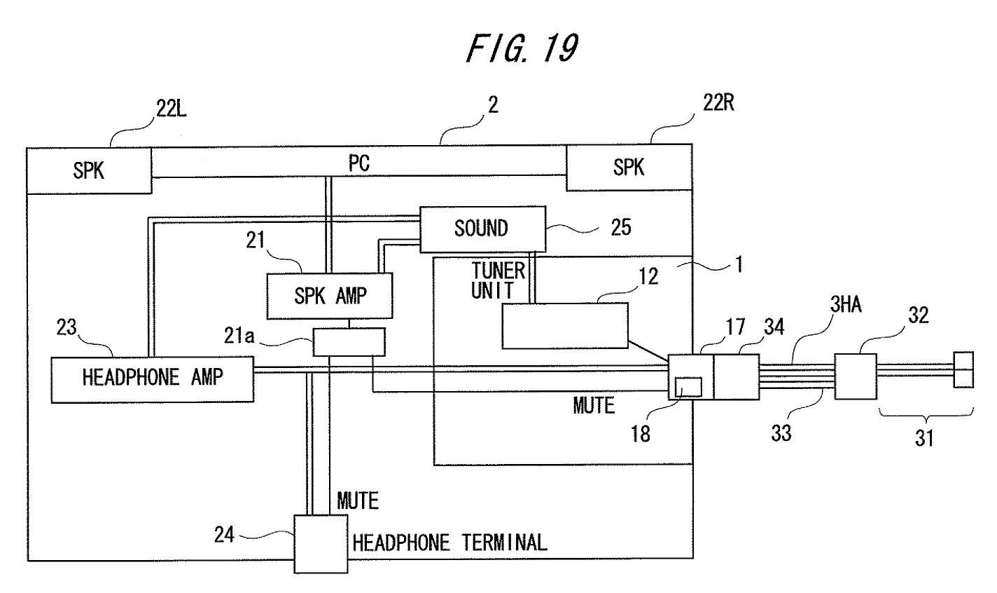

FIG. 19 is a schematic, diagram of a configuration in a sixth embodiment of the present invention. The sixth embodiment is different from the first embodiment discussed above in terms of a point that the mute control unit executes the mute function when detecting the connection of the headphones in place of selecting the mute function by the switch. Note that other constructions are substantially the same as those in the first embodiment, and the repetitive explanations are omitted in a way that marks the same components with the same numerals and symbols.

As illustrated in FIG. 19, in the sixth embodiment, a mute control unit 16 detects which terminal among plural types (three types in the present example) of devices of the antenna 3A, the headphones 3H and the headphone antenna 3HA is connected to the connection unit 11, and outputs the mute signal corresponding to a result of the detection to the loudspeaker amplifier 21 (AND circuit 21a).

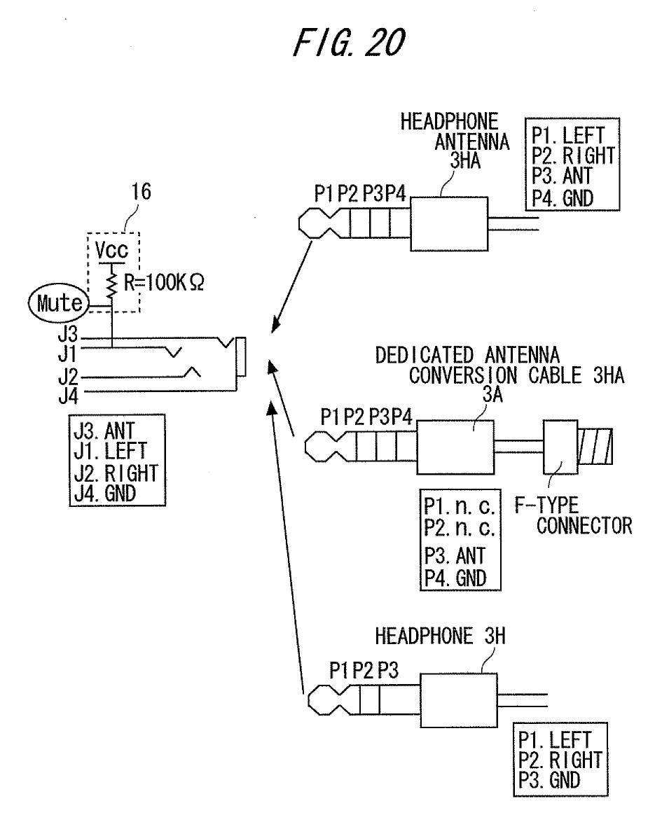

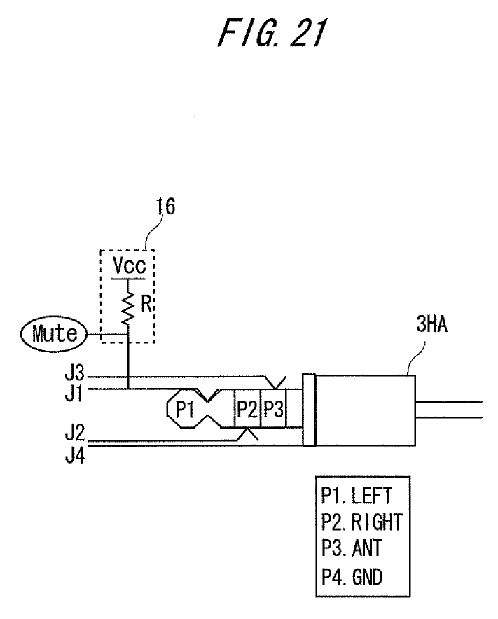

FIG. 20 is an explanatory diagram of the mute control unit 16 that detects the type of the devise. As shown in FIG. 20, the mute control unit 16 is constructed to apply predetermined voltage (e.g., Vcc=3 V to 5V) to a contact point (terminal) J1 or J2 (J1 in the present example) of the connection unit 11. Owing to this construction, in a state where the terminal is not inserted, an output, serving as the mute signal, of the contact point J1 comes to the “High” state of the predetermined voltage value. When the plug of the headphones 3H or the headphone antenna 3HA (FIG. 21 shows the plug of the antenna 3HA) is inserted into the connection unit 11, as illustrated in FIG. 21, the contact point J1 is brought into contact with a left-side contact point P1 of the headphones, and the output, as the mute signal, of the contact point J1 becomes the “Low” state equivalent (approximately 0 V) to GND.

Namely, the mute signal to the loudspeaker amplifier 21 is set “Low” (the mute function is enabled), and the outputs to the loudspeakers 22R, 22L are muted. It should be noted that the connected/unconnected states are detected from the state of the voltage of the contact point leading to the headphones in the present example, however, without being limited to this type of detection, there may be an available scheme capable of outputting the mute signal corresponding to the connecting state of the headphones such as measuring a resistance value between the contact point leading to the headphones and GND, then detecting the connection when the resistance value falls within a predetermined range (e.g., about several tens of ohms (Ω)), and detecting the non-connection when the resistance value exceeds a predetermined value (e.g., infinity).

In the sixth embodiment, the sound output control device in the computer 2 is constructed of the connection unit 11 that detects the types of the output devices 3H and 3HA and the mute control unit 16 that controls the sound outputs based on the electric potential of the contact point J1 or J2 of the connection unit 11.

While on the other hand, when the dedicated antenna 3A is inserted into the connection unit 11, the contact point P1 (P2) of the plug, which comes in contact with the contact point J1 (J2), becomes NC (No Contact), so that the output (mute signal) from the contact point J1 (J2) remains “High”. Namely, the mute control unit 16 sets “High” the mute signal (the mute function is disabled) to the loudspeaker amplifier 21, thereby preventing the outputs to the loudspeakers 22R, 22L from being muted.

As described above, according to the sixth embodiment, when the plug of device is connected to the connection unit 11, the mute function can be set enabled or disabled, corresponding to the type of the device.

Hence, in the receiving device 1 constructed, in the same way as in the fifth embodiment, to connect the antenna and the headphones to the same connection unit and scheming to simplify the device, to reduce the number of components and to save the space, the sound signals can be output from the loudspeaker by automatically disabling the mute function when connecting the antenna to the connection unit.

### <Seventh Embodiment>

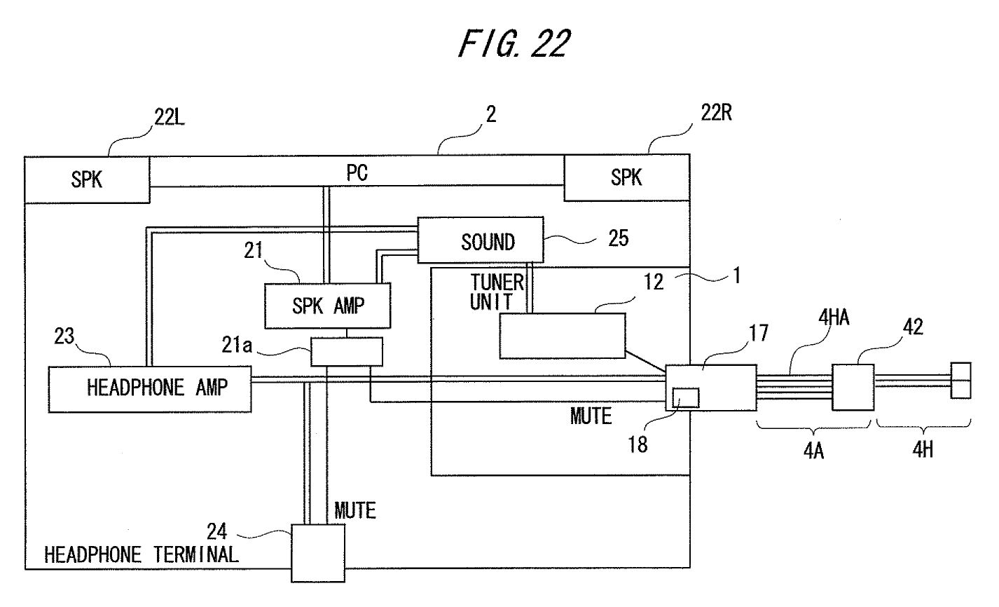

FIG. 22 is a schematic diagram of a configuration in a seventh embodiment of the present invention. The seventh embodiment is different from the first embodiment discussed above in terms of a point taking a scheme of executing the mute function when the mute control unit detects the connection of the headphone element of the headphone antenna instead of selecting the mute function by the switch. Note that other constructions are substantially the same as those in the first embodiment, and the repetitive explanations are omitted in a way that marks the same components with the same numerals and symbols.

As illustrated in FIG. 22, in the seventh embodiment, a headphone antenna 4HA is connected to a connection unit 11. The headphone antenna 4HA is constructed of a base element 4A and a headphone element 4B. The mute control unit 18 detects whether or not the headphone element 4A of the headphone antenna 4HA is connected to the base element 4A, and outputs the mute signal to the loudspeaker amplifier 21 (AND circuit 21a), corresponding to a result of the detection.

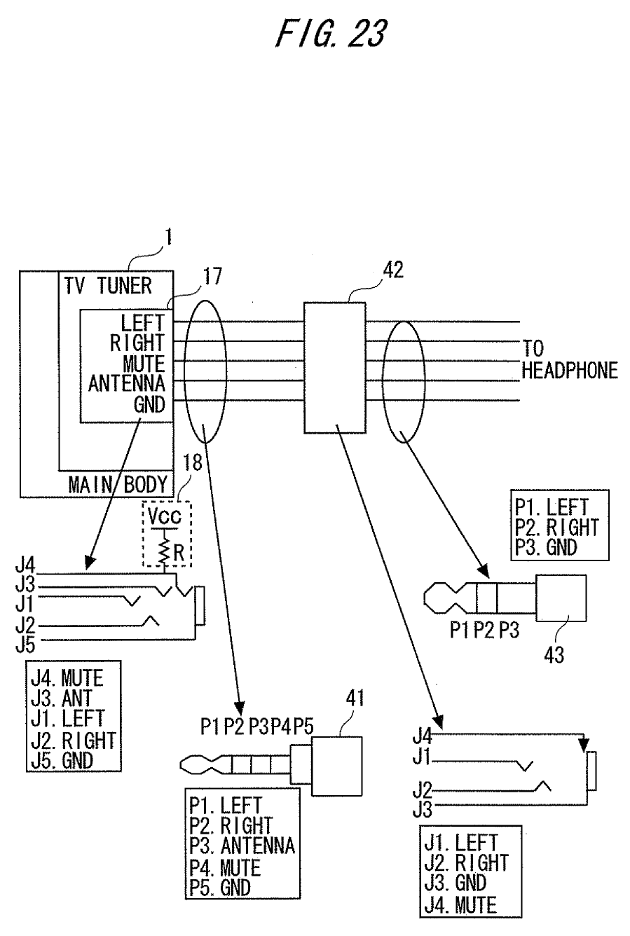

FIG. 23 is an explanatory diagram of the headphone antenna 411A and the mute control unit 18. As shown in FIG. 23, the connection unit 17 of the TV tuner includes the contact points J1 to J5 for the left-and-right sound signals, the antenna, the mute signal and GND. To be specific, a TV tuner side plug 41 of the headphone antenna 4HA has contact points P1-PS coming in contact with J1-J5. The base element 4A includes lines connected to the respective contact points P1-PS, extending from the terminal 41 to the relay unit 42, wherein the line connected to the contact pint P3 functions as an antenna. In the seventh embodiment, the sound output control device in the computer 2 constructed of the connection unit 17 that detects the types of the output devices 4H and 4HA and the mute control unit 18 that controls the sound outputs based on the electric potential of the contact point of the connection unit 17.

The relay unit 42 has the contact point J4 for the mute signal and the contact point J3 for GND, which are provided by side by side. Then, the mute control unit Is applies the predetermined voltage (e.g., Vcc=3 V to 5 V) to the contact point J4 of the connection unit 17. Owing to these contrivances, when the plug 43 of the headphone element 4H is not inserted into the relay unit 42, the contact point J4 becomes the “High” state of the predetermined voltage value. Namely, the mute control unit 18 sets “High” the mute signal (the mute function is disabled) to the loudspeaker amplifier 21, thereby preventing the outputs to the loudspeakers 22R, 22L from being muted.

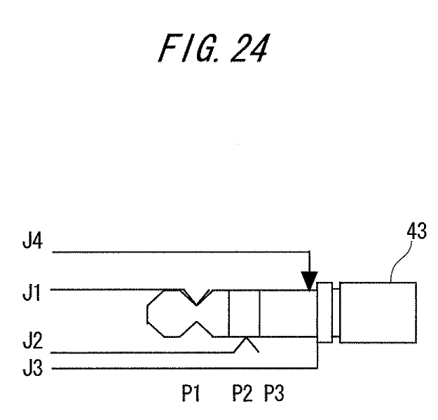

While on the other hand, when the terminal 43 is inserted into the relay unit 42, as illustrated in FIG. 24, the contact point J4 and the contact point J3 become conductive via the terminal 43, and the contact point J4 comes to the “Low” state equivalent (approximately 0 V) to GND. To be specific, the mute control unit 18 sets “Low” the mute signal (the mute function is enabled) to the loudspeaker amplifier 21, thereby muting the outputs to the loudspeakers 22R, 22L.

With this scheme, in the seventh embodiment, the mute function can be set enabled or disabled, depending on whether the headphone element 4H is connected to the relay unit 42 or not.

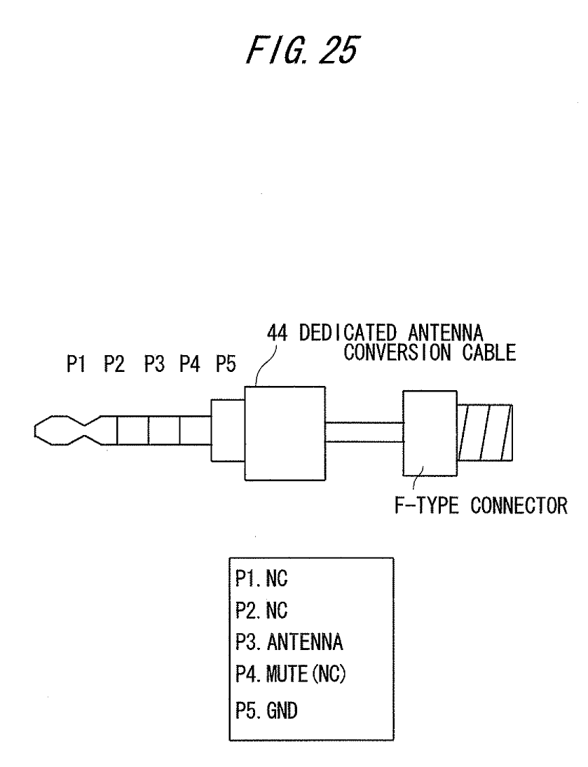

Note that a plug 44 of the dedicated antenna as shown in FIG. 25 may also be connected. In the plug 44 of the dedicated antenna, the contact point P4 for the mute signal becomes NC (No Contact). In this case also, when the plug 44 of the dedicated antenna is connected to the connection unit 17, the contact point 34 remains “High”, and hence the mute control unit 18 can disable the mute function by setting “High” the mute signal.

### <Eighth Embodiment>

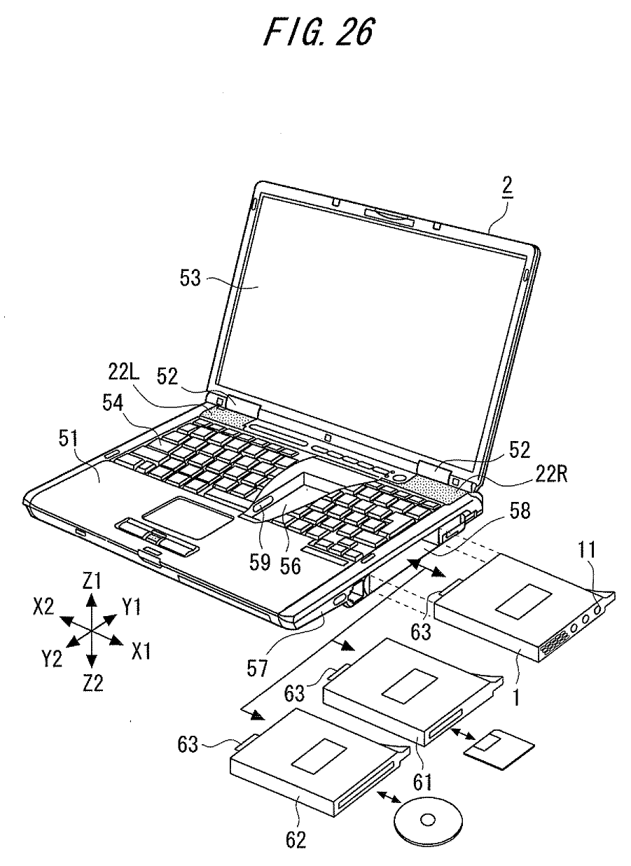

FIG. 26 is a schematic view of an eighth embodiment of the present invention. The eighth embodiment exemplifies the notebook personal computer (which corresponds to the electronic equipment and will hereinafter be abbreviated to the PC) 2 including the same receiving device 1 as in the first embodiment discussed above, which can be inserted and removed as an extended unit. Note that other constructions are substantially the, same as those in the first embodiment, and the repetitive explanations are omitted in a way that marks the same components with the same numerals and symbols.

In FIG. 26, the notebook PC 2 is constructed of the computer main body 51 and the display unit 53 connected to the computer main body 51 in the openable/closable manner via the hinges 52. The arrowheads X1, X2 represent the widthwise direction of the notebook PC 2, the arrowheads Y1, Y2 represent the depthwise direction, and the arrowheads Z1, Z2 indicate the heightwise (thicknesswise) direction. The computer main body 51 has the keyboard unit 54 on its upper surface and the CPU inside, and is formed with the extension bay 56 for accommodating the extended unit in the flower part on the right side. The extension bay 56 has the opening 58 serving as the insertion port for the extended unit in the right-side surface 57 of the computer main body 51. The extension bay 56 takes the slit-like shape extending from the opening 58 up to the middle portion of the device in the direction of the arrowhead X2, and the connector 59 is provided at the X2 side edge portion. Note that the connector 59 is positioned inwardly of the computer main body 51 and is therefore illustrated in a way that clip (omit) part of the upper surface of the main body 51 in FIG. 26.

Further, the tuner unit (receiving device) 1, the FD unit 61 and the CD-ROM unit 62 are prepared as the extended units. Each of these extended units 1, 61, 62 takes the flat-plate-like shape fittable in the extension bay 56, and has the connector 63 fitted to the connector 59 at the front edge portion in the inserting direction (X2). The units 1, 61, 62 are each exclusively fitted in the extension bay 56. This contrivance enables the notebook PC 2 to access the extended units via the connectors 59, whereby the function thereof can be extended.

Namely, the user selects any one of the tuner unit 1, the FD unit 61 and the CD-ROM unit 62 corresponding to the want-to-use function, and fits the selected unit into the extension bay 56. Note that the extension bay 56 might be designated by a variety of terms such as the bay, the extension slot, the multi-bay and the multi-purpose bay.

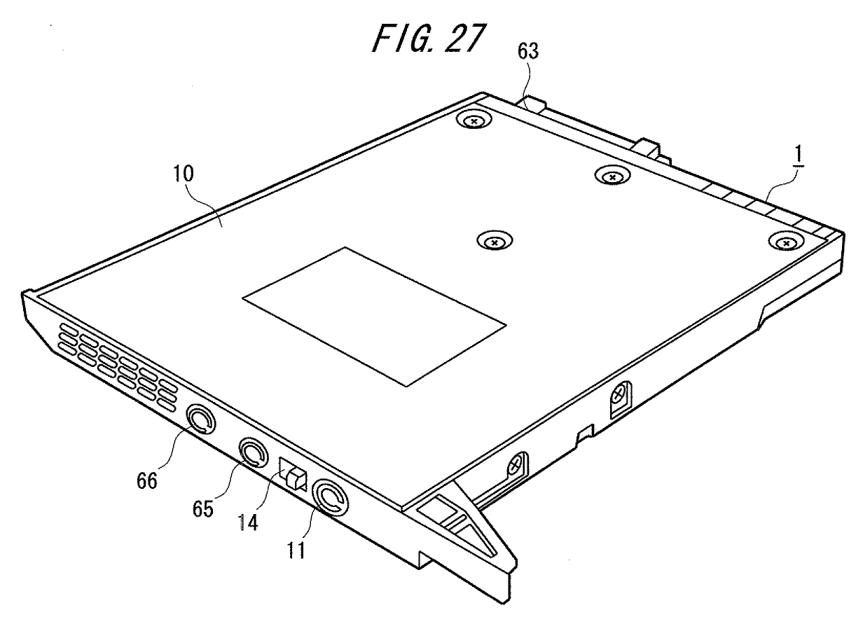

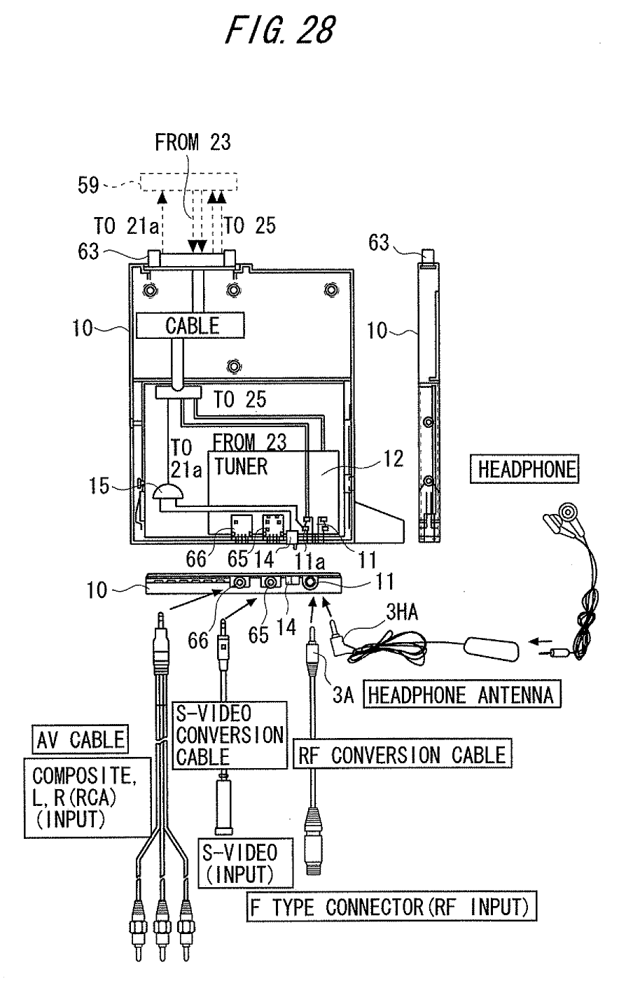

FIG. 27 is a perspective view of an external appearance of the tuner unit 1. FIG. 28 is a schematic diagram of a configuration of the tuner unit 1. As described above, the enclosure 10 takes substantially the flat-plate-like shape as the external configuration thereof, and is provided with the connector 63 protruding from the front edge surface in its inserting direction (X2-direction). Further, the headphone antenna terminal (connection unit) 11, the S-video input terminal 65 and the composite input terminal 66 are provided in line on the rear edge surface in the inserting direction, i.e., an external cladding surface 64 that is positioned outside when fitted into the extension bay 56 and is flush with a right side surface of the note-book PC 2.

In the same way as in the first embodiment discussed above, the decoding unit 12 generates the video signals and the sound signals based on the radio signals (TV broadcast) received via the antenna elements of the antenna 3A or the headphone antenna 3HA connected to the connection unit 11, and outputs these signals to the sound chip 25 via the connector 63.

Further, the sound signals are output from a headphone amplifier 23 via the connector 63, and the sounds are output from the headphones 3H, 3HA connected to the connection unit 11.

Then, the mute control unit 15 transmits the mute signal to the loudspeaker amplifier 21 (AND circuit 21a) through the connector 63 on the basis of the mute signal of the mute indicating unit 11a and the mute control signal of the switch 14. With this operation, in the same way as in the first embodiment discussed above, it is feasible to disable the mute function when the switch 14 selects it to disable the mute, whereby the sounds can be output from the loudspeakers 22R, 22L, even when the plugs 3A, 3HA are connected to the connection unit 11 (Low) in a way that sets “High” the mute signal and thus outputs the High mute signal.

### <First Modified Example>

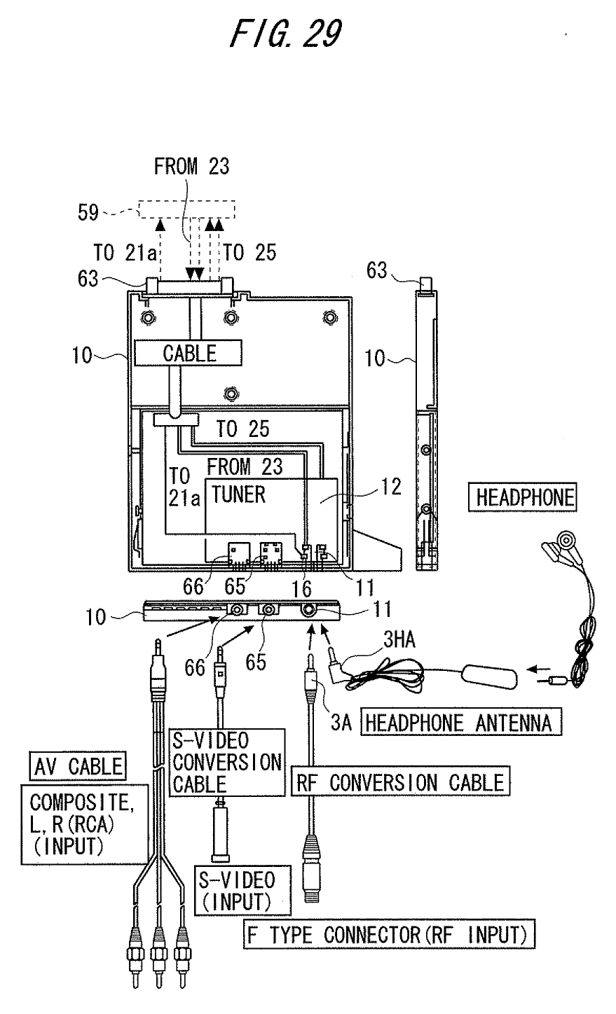

FIG. 29 shows an example in which the receiving device 1 in the sixth embodiment (FIG. 19) is constructed as an extended unit. In the example in FIG. 29, a mute control unit 16 detects which device among plural types (three types in the present example) of devices as the antenna 3A, the headphones 3H and the headphone antenna 3HA is connected to the connection unit 11, and outputs the mute signal corresponding to a result of the detection to the loudspeaker amplifier 21 (AND circuit 21a). Namely, the mute control unit 16, when detecting the connection of the headphones 3H or the headphone antenna 3HA, mutes the output of the loudspeaker by setting “Low” the mute signal, and, when detecting the connection of the antenna 3A, does not mute the output of the loudspeaker by setting “High” the mute signal.

Thus, the mute function can be properly controlled even in the case of constructing the receiving device 1 in the sixth embodiment as the extended unit according to the first modified example.

### <Second Modified Example>

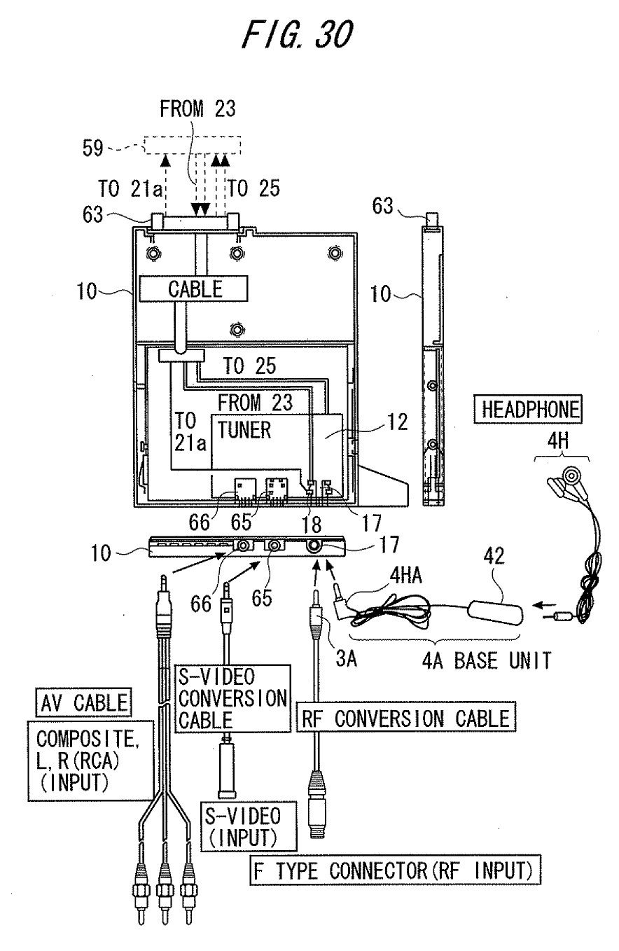

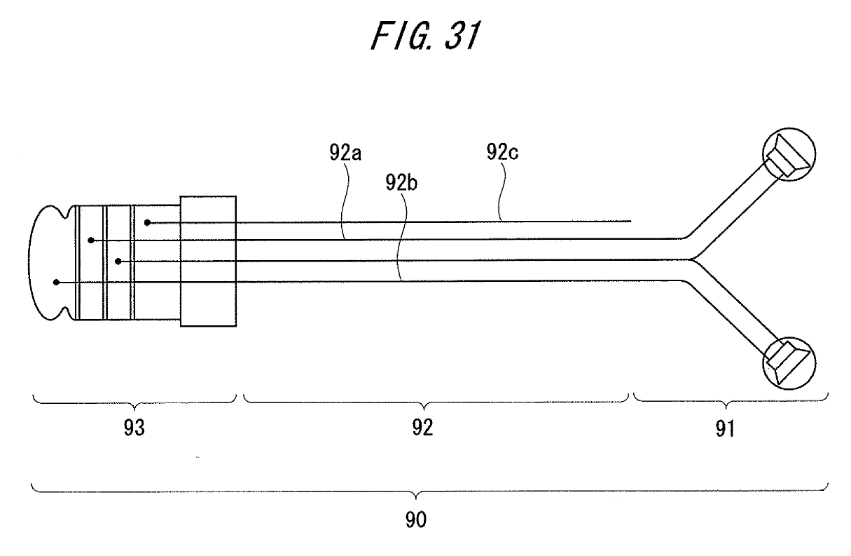

Moreover, FIG. 30 illustrates an example in which the receiving device 1 in the seventh embodiment (FIG. 22) is constructed as an extended unit. A scheme in the example in FIG. 15 is that a mute control unit 18, when detecting the connection of the headphone element 4H of the headphone antenna 4HA connected to the connection unit 17, outputs the mute signal to the loudspeaker amplifier 21 via the connector 63, thereby muting the output of the loudspeaker. The mute control unit 18 applies the predetermined voltage (e.g., Vcc=3 V to 5V) to the contact point J3 of the connection unit 17 as shown in FIG. 23, and, when the plug 43 of the headphone element 4H is not inserted into the relay unit 42, the contact point J4 becomes the “High” state of the predetermined voltage value. Namely, the mute control unit 18 sets “High” the mute signal (the mute function is disabled) to the loudspeaker amplifier 21, thereby preventing the outputs to the loudspeakers 22R, 22L from being muted.

While on the other hand, when the plug 43 is inserted into the relay unit 42, as illustrated in FIG. 24, the contact point J4 and the contact point J3 get conductive through the terminal 43, and the contact point J4 comes Lo the “Low” state equivalent (approximately 0 V) to GND. Namely, the mute control unit 18 mutes the outputs to the loudspeakers 22R, 22L by setting “Low” the mute signal. (the mute function is enabled) to the loudspeaker amplifier 21.

Thus, the mute function can be properly controlled even in the case of constructing the receiving device 1 in the seventh embodiment as the extended unit according to the second modified example.

### INDUSTRIAL APPLICABILITY

The embodiment discussed above has exemplified the personal computer as the electronic equipment to which the output device according to the present invention is connected, however, without being limited to this type of device, available devices may be those capable of processing the information of the received signals and the sound signals to be output. In particular, the present invention is exemplary as the output device of the notebook PC in which a cubic capacity of the device is restricted, a space-saving type PC, a PIDA (Personal Digital Assistant), a mobile phone, etc.

Moreover, the embodiment discussed above has exemplified the headphones, however, without being limited to the headphones, available devices are those that output, as the sounds, the sound signals from the electronic equipment, such as an external loudspeaker. Further, the devices available as the headphones may be those enabling the individual to listen to the sound outputs in a way that attaches the device to the head etc, such as earphones, ear loudspeakers and bone-conduction loudspeakers. Namely, the headphone antenna may be enough by providing these devices with the antennas.

Moreover, according to the present invention, the sounds may be sufficient if being simply the sounds such as music, voices and electronic sounds but are not limited to the TV sounds composed of human voices, the music, etc.

The embodiment discussed above has exemplified the receiving system employing the personal computer, however, the present invention is not limited to this typo of receiving system, the available devices may be those capable of processing the information of the received signals, the sound signals to be output, etc.

Further, the embodiment discussed above has exemplified the example of using the headphones, however, the earphones, the external loudspeaker, etc may also be employed as substitutes for the headphones.

The present invention can be applied widely to the equipment including the antenna and the headphones that are connected to each other, such as the radio, the mobile phone and the portable TV in addition to the TV tuner. The present invention is suited particularly to the notebook PC in which the cubic capacity of the device is restricted, the space-saving type PC, the PDA, the mobile phone, etc.

What is claimed is:

1. An output device that outputs sounds corresponding to sound signals from electronic equipment, comprising:
a connection unit connecting to a connection terminal of said electronic equipment;
a wire unit having one edge portion connected to said connection unit and transmitting the sound signals from said electronic equipment; and
a relay unit connected to an edge portion, opposite to said connection unit, of said wire unit, relaying the sound signals, and having an attachable/detachable output unlit that outputs the sound signals as the sounds,
wherein said connection unit includes a state exhibiting unit exhibiting whether or not said output unit is in a state of being connected to said relay unit.

2. An output device according to claim 1, wherein said state exhibiting unit is a terminal having an electric characteristic that differs depending on the connection state between said output unit and said relay unit.

3. An output device according to claim 2, wherein said relay unit includes a detection unit detecting whether said output unit is connected to said relay unit or not, and
said wire unit includes a signal line transmitting a result of the detection to said connection unit from said relay unit.

4. An output device according claim 1, wherein in said wire unit, the signal line for an antenna or the signal line transmitting the sound signals has an antenna function, and
said connection unit includes an output terminal outputting, to said electronic equipment, the signals received from the signal line for the antenna or the signal line transmitting the sound signals.

5. An output device according to any one of claims 1 through 4, wherein said output device is used in the way of being connected to said electronic equipment that mutes the sound signals, corresponding to the electric characteristic of the state exhibiting unit.

6. An output device according to claims 1, wherein said output unit connects to said relay unit in an attachable/detachable manner and outputs the sound signals as the sounds from said relay unit.

7. An output device according to claim 1, wherein said relay unit includes a switching unit performing switchover as to whether said state exhibiting unit is made to exhibit or not.

8. An output device according to claim 7, wherein said state exhibiting unit includes a circuit that closes when said output unit is connected to said relay unit and opens when said output unit is disconnected from said relay unit, and
said switching unit is a switch that opens and closes said circuit separately from the connection.

9. An output device that outputs sounds corresponding to sound signals from electronic equipment, comprising:
a connection unit connecting to a connection terminal of said electronic equipment;
a wire unit having one edge portion connected to said connection unit and transmitting the sound signals from said electronic equipment;
an output unit connected to an edge portion, opposite to said connection unit, of said wire unit, and outputting the sound signals as the sounds; and
a switching unit positioned between said connection unit and said output unit on said wire unit and switching over a state exhibited to said electronic equipment via said wire unit.

10. A sound output control device in electronic equipment that outputs sound from a first speaker, comprising:
a mute indicating unit detecting whether or not a terminal of an antenna and/or a second speaker has been connected a connection unit to which said terminal is connected, making said first speaker output the sound signals when said terminal is not connected to said connection unit, and muting the output to said first speaker when said terminal is connected to said connection unit; and
a mute control unit disabling a mute function of said mute indicating unit when a switch for selecting enabled/disabled statuses of the mute selects the mute-disabled status, and outputting the sound signals to said first speaker even when said terminal is connected to said connection unit.

11. A sound output control device according to claim 10, further comprising, said switch being provided in said second speaker, a detection unit detecting a state of said switch.

12. A sound output control device in electronic equipment that outputs sounds from a first speaker, comprising:
a mute control unit detecting a type of a terminal connected to a connection unit to which an antenna and/or a second speaker are or is connected, muting an output to said first speaker when said second speaker is connected to said connection unit, then disabling a mute function when said second speaker is not connected to said connection unit, and thus outputs the sounds from said first speaker.

13. A sound output control device in electronic equipment that outputs sounds from a first speaker, comprising:
a mute control unit detecting whether or not a second speaker element is connected to an antenna connected to a connection unit to which an attachable/detachable antenna of said second speaker element is connected, muting an output to said first speaker when said second speaker element is connected, then disabling a mute function when said second speaker element is not connected to said connection unit, and outputs the sounds from said first speaker.

14. A sound output control device according to claim 12, wherein even when muting the output to said first speaker, if a switch for selecting enabled/disabled statuses of the mute selects the mute-disabled status, outputs the sounds from said first speaker

15. A receiving device in electronic equipment that receives radio signals and outputs sound signals from a first speaker, comprising:
a connection unit to which a terminal of an antenna and/or a second speaker are or is connected;
a receiving unit receiving the radio signals via said antenna connected to said connection unit;
a mute indicating unit detecting whether or not said terminal is connected to said connection unit, outputting sound signals to said first speaker when said terminal is not connected to said connection unit, and muting the output to said first speaker when said terminal is connected to said connection unit;
a switch selecting enabled/disabled statuses of the mute; and
a mute control unit disabling a mute function of said mute indicating unit when said switch selects the mute-disabled status, and outputting the sound signals to said first speaker even when said terminal is connected to said connection unit.

16. A receiving device according to claim 15, further comprising, said switch being provided in said second speaker, a detection unit detecting a state of said switch.

17. A receiving device in electronic equipment that receives radio signals and outputs sound signals from a first speaker, comprising:
a connection unit to which an antenna and/or a second speaker are or is connected;
a receiving unit receiving the radio signals via said antenna connected to said connection unit;
a mute controlling unit detecting a type of a terminal connected to said connection unit, muting an output to said first speaker when said second speaker is connected to said connection unit, then disabling the mute function when said second speaker is not connected, and outputting the sound signals to said first speaker.

18. A receiving device according to claim 17, wherein even when muting the output to said first speaker, it a switch for selecting enabled/disabled statuses of the mute selects the mute-disabled status, output the sounds from said first speaker.

19. A receiving device in electronic equipment that receives radio signals and outputs sounds from a first speaker, comprising:
a connection unit to which an attachable/detachable antenna of a second speaker element is connected;
a receiving unit receiving radio signals via said antenna connected to said connection unit; and
a mute control unit detecting whether or not said second speaker element is connected to said antenna connected to said connection unit, muting an output to said first speaker when said second speaker element is connected, then disabling a mute function when said second speaker element is not connected to said connection unit, and outputting the sounds from said first speaker.

20. A receiving device according to claim 19, wherein even when muting the output to said first speaker, if a switch for selecting enabled/disabled statuses of the mute selects the mute-disabled status, outputs the sounds from said first speaker.

21. A receiving device according to claim 18, wherein said switch is provided in said second speaker.

22. A receiving device according to claim 15, wherein said receiving device is an extended unit connected, exclusively of other extended units, to an extension slot of said electronic equipment.

23. A receiving device according to claim 15, further comprising a TV tuner unit generating video data and sound data from radio wave signals of a TV broadcast received as radio signals.

24. A receiving system that receives radio signals and outputs sound signals from a first speaker, comprising:
a connection unit to which a terminal of an antenna and/or a second speaker are or is connected;
a receiving unit receiving the radio signals via said antenna connected to said connection unit;
an output unit outputting sounds from said first speaker on the basis of the sound signals as radio signals, and, on the other hand, muting an output of the sounds in accordance with a mute signal;
a mute indicating unit detecting whether or not said terminal is connected to said connection unit, notifying said output unit of the mute signal on the basis of a result of the detection, outputting the sound signals to said first speaker when said terminal is not connected to said connection unit, and muting the output to said first speaker when said terminal is connected to said connection unit,
a switch selecting enabled/disabled statuses of the mute; and
a mute control unit disabling a mute function of said mute indicating unit when said switch selects the mute-disabled status, and outputting the sounds from said first speaker even when said terminal is connected to said connection unit.

25. A receiving system according to claim 24, further comprising, said switch being provided in said second speaker, a detection unit detecting a state of said switch.

26. A receiving system according to claim 24, further comprising an extension slot capable of exclusively connecting plural types of extended units,
wherein said connection unit, said receiving unit and said mute indicating unit are provided as said extended units.

27. A receiving system that receives radio signals and outputs sounds from a first speaker, comprising:
a connection unit to which a terminal of an antenna and/or a second speaker are or is connected;
a receiving unit receiving the radio signals via said antenna connected to said connection unit;
an output unit outputting sounds from said first speaker on the basis of the sound signals as radio signals, and, on the other hand, muting an output of the sounds in accordance with a mute signal; and
a mute control unit detecting a type of said terminal connected to said connection unit, notifying said output unit of the mute signal on the basis of a result of the detection, muting the output to said first speaker when said second speaker is connected to said connection unit, then disabling a mute function when said second speaker is not connected to said connection unit, and outputting the sounds from said first speaker.

28. A receiving system according to claim 27, wherein even when muting the output to said first speaker, if a switch for selecting enabled/disabled statuses of the mute selects the mute disabled status, outputs the sounds from said first speaker.

29. A receiving system that receives radio signals and outputs sound signals from a first speaker, comprising:
a connection unit to which an attachable/detachable antenna of a second speaker element is connected;
a receiving unit receiving the radio signals via said antenna connected to said connection unit;
an output unit outputting sounds from said first speaker on the basis of the sound signals as radio signals, and, on the other hand, muting an output of the sounds in accordance with a mute signal; and
a mute control unit detecting whether or not said second speaker element is connected to said antenna connected to said connection unit, notifying said output unit of the mute signal on the basis of a result of the detection, muting the output to said first speaker when said second speaker element is connected to said connection unit, then disabling a mute function when said second speaker element is not connected to said connection unit, and outputting the sounds from said first speaker.

30. A receiving system according to claim 29, wherein even when muting the output to said first speaker, if a switch for selecting enabled/disabled statuses of the mute selects the mute-disabled status, outputs the sounds from said first speaker.

31. A receiving system according to claim 27, further comprising an extension slot capable of exclusively connecting plural types of extended units,
wherein said connection unit, said receiving unit and said mute indicating unit are provided as said extended units.
